(19) United States
(12) Patent Application Publication
(10) Pub. No.: US 2024/0233821 A9
(43) Pub. Date: Jul. 11, 2024

(54) 3D CELLS AND ARRAY STRUCTURES AND PROCESSES

(71) Applicant: Fu-Chang Hsu, San Jose, CA (US)

(72) Inventor: Fu-Chang Hsu, San Jose, CA (US)

(21) Appl. No.: 18/489,842

(22) Filed: Oct. 18, 2023

Related U.S. Application Data
(60) Provisional application No. 63/417,535, filed on Oct. 19, 2022.
(60) Provisional application No. 63/417,606, filed on Oct. 19, 2022.
(60) Provisional application No. 63/418,011, filed on Oct. 20, 2022.
(60) Provisional application No. 63/418,534, filed on Oct. 22, 2022.
(60) Provisional application No. 63/421,522, filed on Nov. 1, 2022.
(60) Provisional application No. 63/458,634, filed on Apr. 11, 2023.
(60) Provisional application No. 63/459,406, filed on Apr. 14, 2023.
(60) Provisional application No. 63/460,406, filed on Apr. 19, 2023.
(60) Provisional application No. 63/463,040, filed on Apr. 30, 2023.
(60) Provisional application No. 63/465,526, filed on May 10, 2023.
(60) Provisional application No. 63/466,155, filed on May 12, 2023.
(60) Provisional application No. 63/467,004, filed on May 16, 2023.
(60) Provisional application No. 63/542,526, filed on Oct. 5, 2023.

(51) Int. Cl. H10B 53/20; H10B 12/00; H10B 53/10; H10B 61/00; H10B 63/00; H10B 63/10

(52) U.S. Cl. CPC H10B 53/20; H10B 12/482; H10B 53/10; H10B 61/22; H10B 63/10; H10B 63/84

(57) ABSTRACT

Various 3D cells, array structures and processes are disclosed. In an embodiment, a memory cell structure is provided that includes a vertical bit line, an insulator surrounding a first portion of vertical bit line, a continuous semiconductor layer surrounding the insulator and a second portion of the vertical bit line, and an extended portion of conductor material surrounding the continuous semiconductor layer. The memory cell structure also includes a first dielectric layer surrounding extended portion of conductor material, a first conductor layer surrounding the first dielectric layer, a second conductor layer surrounding the first conductor layer, a second dielectric layer on a top surface of the first and second conductor layers, a third dielectric layer on a bottom surface of the first and second conductor layers, a first gate on a top surface of the second dielectric layer, and a second gate on a bottom surface of the third dielectric layer.

### CROSS-REFERENCE TO RELATED APPLICATIONS

This application claims the benefit of priority under 35 U.S.C. 119(e) based upon U.S. Provisional patent application having Application No. 63/417,535 filed on Oct. 19, 2022, and entitled “3D Cell and Array Structures,” and U.S. Provisional patent application having Application No. 63/417,606 filed on Oct. 19, 2022, and entitled “3D Memory Cell and Array Structures,” and U.S. Provisional patent application having Application No. 63/418,011 filed on Oct. 20, 2022, and entitled “3D Cell and Array Structures,” and U.S. Provisional patent application having Application No. 63/418,534 filed on Oct. 22, 2022, and entitled “3D Array Structures and Processes,” and U.S. Provisional patent application having Application No. 63/421,522 filed on Nov. 1, 2022, and entitled “3D Cell and Array Structures,” and U.S. Provisional patent application having Application No. 63/458,634 filed on Apr. 11, 2023, and entitled “3D Cell and Array Structures,” and U.S. Provisional patent application having Application No. 63/459,406 filed on Apr. 14, 2023, and entitled “3D Cell and Array Structures and Processes,” and U.S. Provisional patent application having Application No. 63/460,406 filed on Apr. 19, 2023, and entitled “3D Memory Cell and Array Structures,” and U.S. Provisional patent application having Application No. 63/463,040 filed on Apr. 30, 2023, and entitled “3D Memory Cell and Array Structures,” and U.S. Provisional patent application having Application No. 63/465,526 filed on May 10, 2023, and entitled “3D Cell and Array Structures,” and U.S. Provisional patent application having Application No. 63/466,155 filed on May 12, 2023, and entitled “3D Cell and Array Structures,” and U.S. Provisional patent application having Application No. 63/467,004 filed on May 16, 2023, and entitled “3D Cell and Array Structures,” and U.S. Provisional patent application having Application No. 63/542,526 filed on Oct. 5, 2023, and entitled “3D Array Structures and Processes,” all of which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use a three-dimensional (3D) array structure. However, cost-effective 3D array structures have not been fully realized.

### SUMMARY

In various exemplary embodiments, three-dimensional (3D) memory cells, array structures, and associated processes are disclosed. In one embodiment, the aspects of the invention are applied to form dynamic random-access memory (DRAM). In another embodiments, aspects of the invention are applied to form a ferroelectric random-access memory (FRAM), resistive random-access memory (RRAM), phase change memory (PCM), and magneto-resistive random-access memory (MRAM). In still other embodiments, aspects of the invention are applicable to form memory elements called ‘synapses’ in artificial neural networks, and to any other memory applications.

In an exemplary embodiment, a memory cell structure is provided that comprises a vertical bit line, an insulator surrounding a first portion of vertical bit line, a continuous semiconductor layer surrounding the insulator and a second portion of the vertical bit line, and an extended portion of conductor material surrounding the continuous semiconductor layer. The memory cell structure also includes a first dielectric layer surrounding extended portion of conductor material, a first conductor layer surrounding the first dielectric layer, a second conductor layer surrounding the first conductor layer, a second dielectric layer on a top surface of the first and second conductor layers, a third dielectric layer on a bottom surface of the first and second conductor layers, a first gate on a top surface of the second dielectric layer, and a second gate on a bottom surface of the third dielectric layer.

In an exemplary embodiment, a memory cell structure is provided that comprises a vertical bit line, an insulator surrounding a first portion of vertical bit line, a continuous semiconductor layer surrounding the insulator and a second portion of the vertical bit line, an extended portion of conductor material surrounding a portion of the continuous semiconductor layer, a first dielectric layer on a top surface of the extended portion of conductor material, a second dielectric layer on a bottom surface of the extended portion of conductor material, a first conductor layer on a top surface of the first dielectric layer, and a second conductor layer on a bottom surface of the second dielectric layer.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIGS. 1A-D show an embodiment of a cell structure for use in a 3D array according to the invention.

FIG. 1E-F shows an embodiment of a 3D cell structure according to the invention.

FIG. 1G shows an embodiment of a 3D cell structure according to the invention.

FIGS. 2A-E shows equivalent circuits of cell structure embodiments for DRAM, FRAM, RRAM, PCM and MRAM, respectively.

FIGS. 3A-B show an embodiment of a 3D cell structure according to the invention.

FIGS. 4A-B show an embodiment of a 3D cell structure according to the invention.

FIGS. 5A-B show an embodiment of a 3D cell structure according to the invention.

FIGS. 6A-B show an embodiment of a 3D cell structure according to the invention.

FIGS. 7A-H show embodiments of brief process steps configured to form 3D cell structures according to the invention.

FIGS. 8A-I show embodiments of a 3D array structure according to the invention.

FIG. 9A shows an embodiment of a 3D array structure according to the invention.

FIG. 9B shows an embodiment of a 3D array structure according to the invention.

FIGS. 10A-B show an embodiment of a 3D cell structure according to the invention.

FIGS. 10C-D show an embodiment of a 3D cell structure according to the invention.

FIGS. 11A-B show an embodiment of a 3D cell structure according to the invention.

FIGS. 12A-J show embodiments of brief process steps configured to form the 3D cell structure shown in FIG. 10A.

FIGS. 12K-N show embodiments of brief process steps configured to form the 3D cell structure shown in FIG. 10C.

FIGS. 12O-S show embodiments of a 3D array structure according to the invention

FIGS. 13A-D show an embodiment of a 3D cell structure according to the invention.

FIGS. 14A-B show an embodiment of a 3D cell structure according to the invention.

FIG. 15A shows a side view of an embodiment of a 3D cell structure according to the invention.

FIG. 15B shows a side view of an embodiment of a 3D cell structure according to the invention.

FIGS. 15C-D show an embodiment of a 3D cell structure according to the invention.

FIGS. 16A-B shows an embodiment of a 3D cell structure according to the invention.

FIGS. 17A-B shows side views of an embodiment of a 3D cell structure according to the invention.

FIGS. 18A-C shows side views of a 3D cell structure according to the invention.

FIGS. 19A-B show embodiments of cell structures having source line configurations similar to the cell structure embodiments shown in FIG. 14A and FIG. 15A.

FIG. 20A shows a side view of an embodiment of a 3D cell structure according to the invention.

FIG. 20B shows a side view of an embodiment of a 3D cell structure according to the invention.

FIG. 21A shows a side view of an embodiment of a 3D cell structure according to the invention.

FIG. 21B shows a side view of an embodiment of a 3D cell structure according to the invention.

FIGS. 22A-C shows an embodiment of a 3D cell structure according to the invention.

FIG. 23 shows an embodiment of a 3D cell structure according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

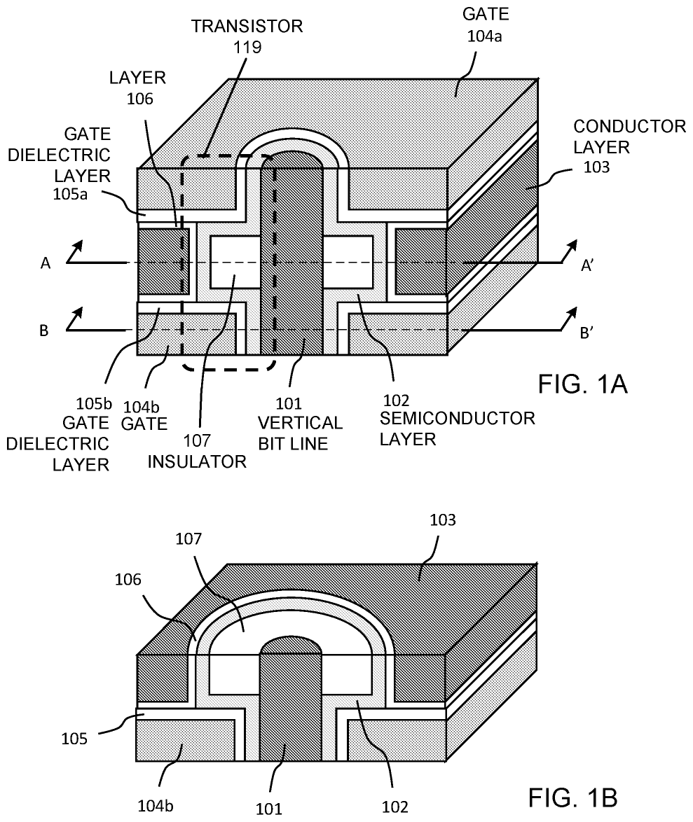

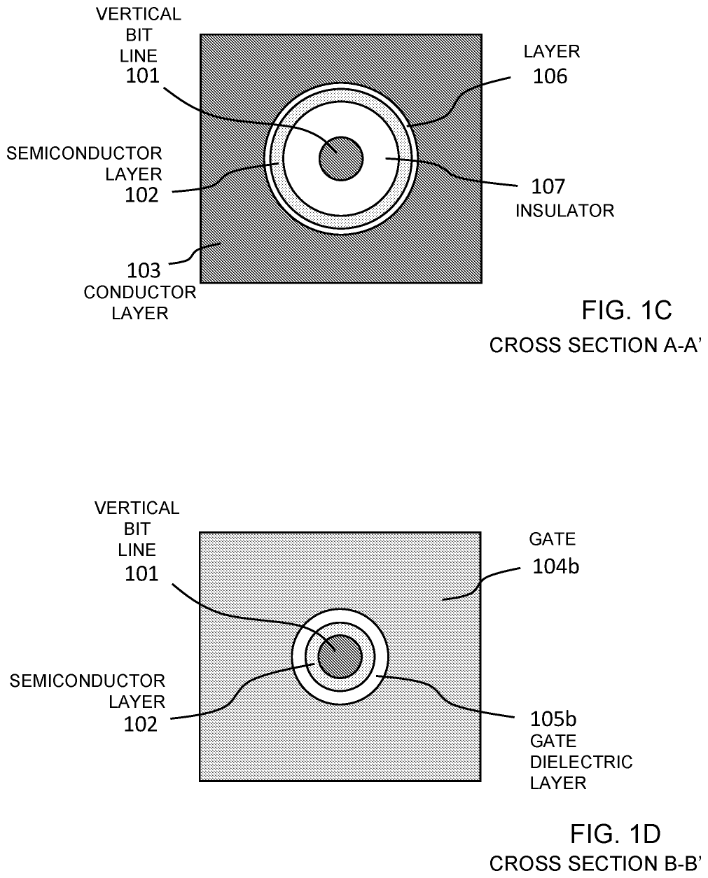

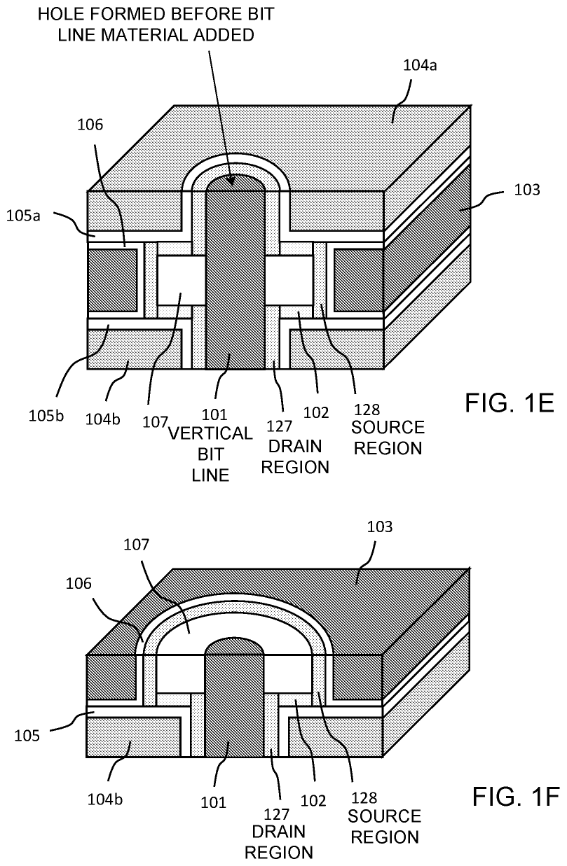

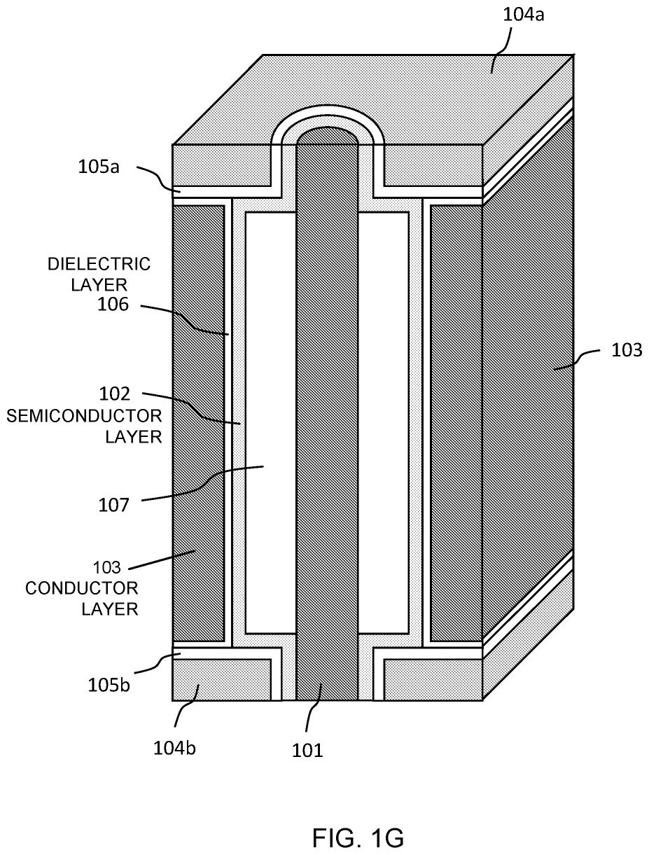

In various exemplary embodiments, three-dimensional (3D) memory cells, array structures, and associated processes are disclosed. For example, embodiments of the invention are related to 3D NOR-type cells and array structures. However, aspects of the invention can be applied to many different memory technologies. In one embodiment, aspects of the invention are applied to form dynamic random-access memory (DRAM). In other embodiments, aspects of the invention are applied to form ferroelectric random-access memory (FRAM), resistive random-access memory (RRAM), phase change memory (PCM), and magneto-resistive random-access memory (MRAM). In another embodiment, aspects of the invention are applied to form memory elements called ‘synapses’ in artificial neural networks. In addition, aspects of the invention are applicable to form a variety of other memory structures and applications. FIG. 1A show an embodiment of a cell structure for use in a 3D array according to the invention.

FIG. 1B shows the cell structure shown in FIG. 1A with a gate 104a and gate dielectric layer 105a removed to show the inner structure of the cell.

FIGS. 1C-D shows cross-section views of the cell structure shown in FIG. 1A taken along lines A-A′ and B-B′, respectively. It should be note that in some cross section views shown herein, additional material of the structural components that surround the bit line are shown for clarity.

The cell structure comprises a vertical bit line (BL) 101 formed of conductor material, such as metal or heavily doped semiconductor material, such as polysilicon. The cell structure includes a semiconductor layer 102 formed of material, such as silicon, polysilicon, germanium, silicon germanium, gallium arsenide, cadmium selenide, indium gallium zinc oxide (IGZO), or any other suitable semiconductor material. The semiconductor layer 102 forms a channel of the cell transistor. In one embodiment, the semiconductor layer 102 is doped with P-type or N− type of impurity, such as boron or phosphorus, respectively, by using diffusion, implantation, or in-situ doping processes.

The cell structure includes gates 104a-b formed of conductor material, such as metal or polysilicon material. The cell structure also includes gate dielectric layers 105a-b that comprise material such as thin oxide or high-K material such as hafnium oxide (HfO2). An insulator 107 is also provided that comprises insulating material, such as oxide or nitride. The gates 104a-b can be connected to word lines (WL) of a memory array. The gates 104a-b, gate dielectric layers 105a-b, and semiconductor layer 102 form a dual-gate thin-film transistor 119. The source and drain of the transistor are connected to the layer 106 and the bit line 101, respectively.

Depending on the cell technologies, the layer 106 can be formed of different materials. In one embodiment for dynamic random-access memory (DRAM), the layer 106 is a dielectric layer comprising material such as thin oxide or high-K material such as HfO2. A conductor layer 103 comprises material, such as metal or polysilicon material. The conductor layer 103, dielectric layer 106, and semiconductor layer 102 form a capacitor.

In another embodiment that forms a ferroelectric random-access memory (FRAM), the layer 106 comprises multiple layers including a ferroelectric layer such as lead zirconate titanate (PZT), hafnium oxide (HfO2) in orthorhombic crystal phase, or hafnium zirconium oxide (HfZrO2), and a buffer layer such as oxide or high-K material such as HfO2.

In another embodiment that forms a resistive random-access memory (RRAM), the layer 106 comprises multiple layers including an adjustable resistive layer, such as hafnium oxide (HfOx), titanium oxide (TiOx), and tantalum oxide (TaOx).

In another embodiment that forms a phase-change memory (PCM), the layer 106 comprises multiple layers including a phase-change layer, such as chalcogenide glass, Ge2Sb2Te5 (GST).

In another embodiment that forms a magneto-resistive random-access memory (MRAM), the layer 106 comprises multiple layers including a top layer and a bottom layer formed of ferromagnetic material, such as iron-nickel (NiFe) or iron-cobalt (CoFe) alloys, and a middle tunnel-barrier layer formed of thin insulator such as hafnium oxide (HfO2).

It should be noted that the materials forming the layer 106 described above are exemplary and not limiting and that any other suitable materials can be used to form the layer 106 within the scope of the invention. For illustration, the following description will use dielectric material in the embodiments. However, any other suitable materials are within the scope of the invention.

FIG. 1E shows an embodiment of a 3D cell structure according to the invention.

FIG. 1F shows the cell structure shown in FIG. 1E with a gate 104a and a gate dielectric layer 105a removed to show the inner structure of the cell. This embodiment is similar to the embodiment shown in FIG. 1A except that a heavily doped drain region 127 and source region 128 are formed in the semiconductor layer 102. In one embodiment, the drain 127 and source 128 regions have the opposite type of doping from the semiconductor layer 102 to form a junction transistor. In another embodiment, the drain 127 and source 128 regions have the same type of doping as the semiconductor layer 102 to form a junction-less transistor.

In one embodiment, the drain region 127 is formed by applying a diffusion process through a bit line hole, created to form the bit line 101, to diffuse impurity into the semiconductor layer 102 before the bit line 101 is formed. The source region 128 is formed by applying a diffusion process to diffuse impurity into the semiconductor layer 102 before the conductor layer 103 is formed.

FIG. 1G shows another embodiment of a 3D cell structure according to the invention. This embodiment is similar to the embodiment shown in FIG. 1A except that the height of the cell is increased to increase the area of the dielectric layer 106 between the semiconductor layer 102 and the conductor layer 103. For a DRAM cell embodiment, the conductor layer 103, the dielectric layer 106, and the semiconductor layer 102 form a capacitor for electric charge storage. Increasing the height of the cell increases the value of the capacitor to increase the electric charge stored in the capacitor. Therefore, the data retention time for the DRAM cell is increased.

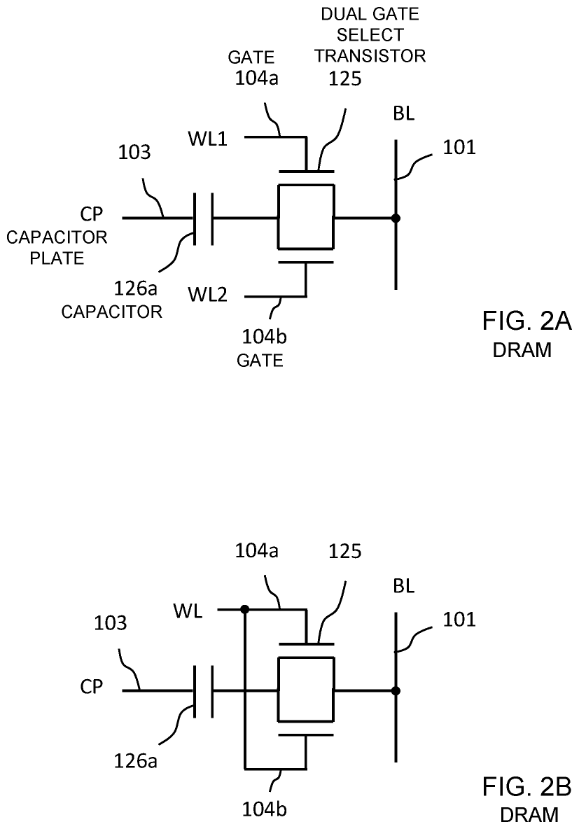

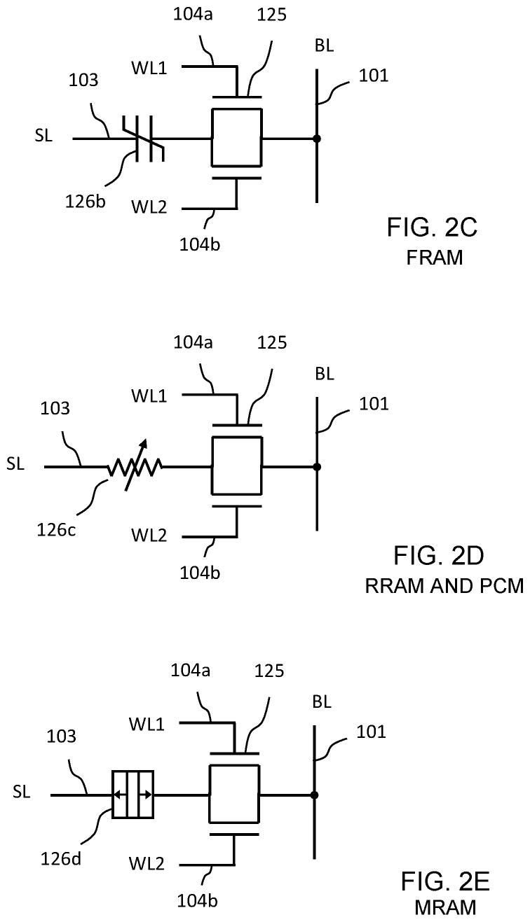

FIGS. 2A-E shows equivalent circuits of cell structure embodiments for DRAM, FRAM, RRAM, PCM and MRAM, respectively. In one embodiment, the circuits of the cell structures comprise a dual gate select transistor 125 and a selected memory element (e.g., memory elements 126a-d). The dual gate select transistor 125 comprises gates 104a and 104b. The gates 104a and 104b are connected to word lines, WL1 and WL2, respectively. In another embodiment shown in FIG. 2B, the gates 104a and 104b are connected to the same word line (WL) to form a single-gate transistor. The memory elements 126a to 126d are formed of the conductor layer 103, the layer 106, and the semiconductor layer 102. In another embodiment, the dielectric layer 106 is formed of different materials to form various types of memory cells, as described with respect to FIG. 1A.

FIG. 2A illustrates an embodiment for a DRAM cell where the memory element 126a is a capacitor. The capacitor is connected to a conductor layer 103 that forms a conductor plate or also called a capacitor plate (CP). The conductor plate can be supplied with a constant voltage, such as VDD or ½ VDD.

FIG. 2B illustrates an embodiment for a DRAM cell where the memory element 126a is a capacitor. This embodiment is similar to the embodiment shown in FIG. 2A except that the gates 104a and 104b of the dual-gate transistor 125 are connected together.

FIG. 2C illustrates an embodiment for an FRAM cell where the memory element 126b is a ferroelectric capacitor. The ferroelectric capacitor is connected to a conductor layer 103 that forms a source line (SL).

FIG. 2D illustrates embodiments for RRAM and PCM cells where the memory element 126c is either a resistive memory element or phase-change memory element, respectively. The memory element 126c is connected to a conductor layer 103 that forms a source line (SL).

FIG. 2E illustrates an embodiment for an MRAM cell where the memory element 126d is a magneto-resistive memory element. The magneto-resistive memory element 126d is connected to a conductor layer 103 that forms a source line (SL).

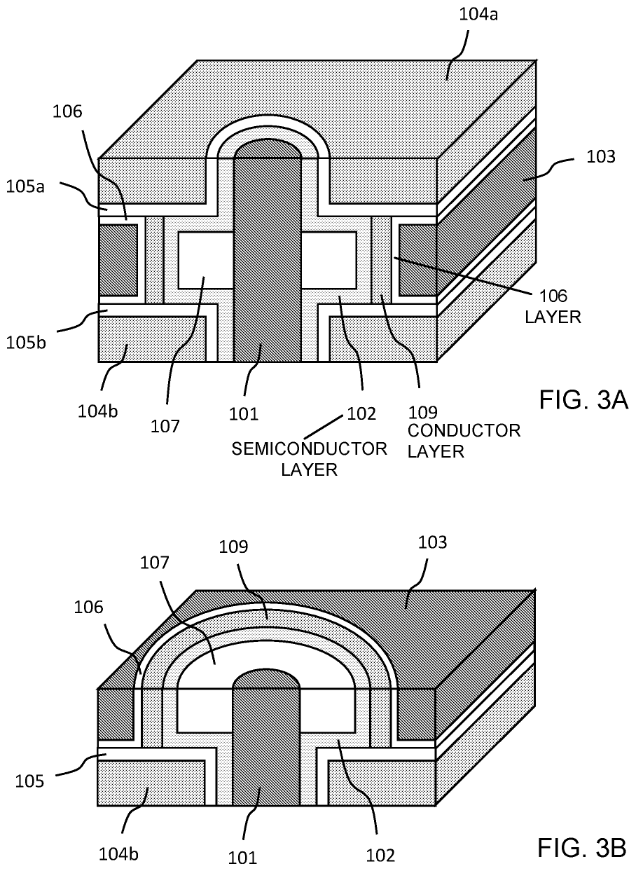

FIG. 3A shows an embodiment of a 3D cell structure according to the invention. This embodiment is similar to the embodiment shown in FIG. 1A except that a conductor layer 109 comprising material such as metal is added between the dielectric layer 106 and the semiconductor layer 102 as shown. For some special types of technologies, the conductor layer 109 is formed of specific metal material that is necessary to form the memory element. For example, for an RRAM memory element embodiment, the conductor layer 109 is formed of titanium (Ti), platinum (Pt), Copper (Cu), Gold (Au), and other suitable materials.

FIG. 3B shows the cell structure of FIG. 3A with the gate 104a and gate dielectric layer 105a removed to show the inner structure of the cell.

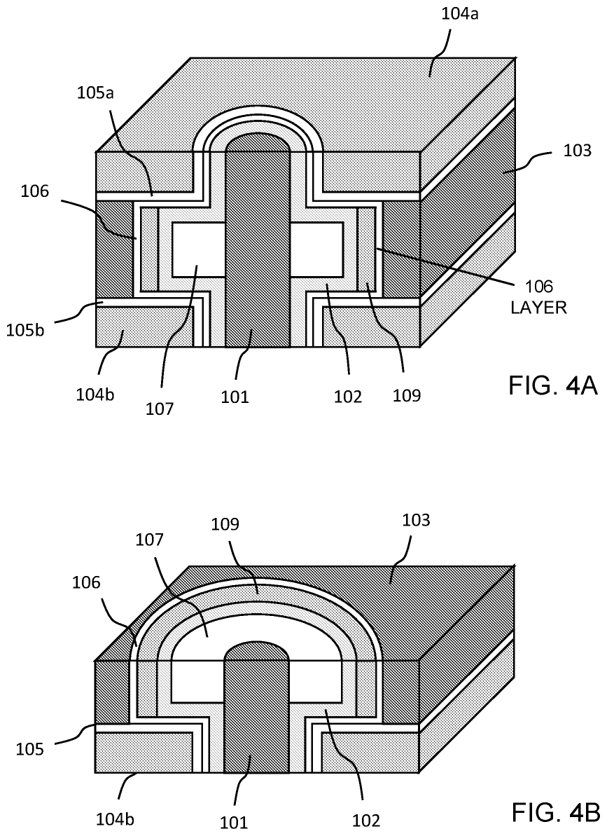

FIG. 4A shows another embodiment of a 3D cell structure according to the invention. This embodiment is similar to the embodiment shown in FIG. 1A except that the dielectric layer 106 is formed in another way. In the cell structure shown in FIG. 1A, the dielectric layer 106 is formed through the space occupied by the conductor layer 103 before the conductor layer 103 is formed. In the cell structure shown in FIG. 4A, the dielectric layer 106 is formed through the vertical bit line hole before the conductor layer 109 and the semiconductor layer 102 are formed.

FIG. 4B shows the cell structure shown in FIG. 4A with the gate 104a and gate dielectric layer 105a removed to show the inner structure of the cell.

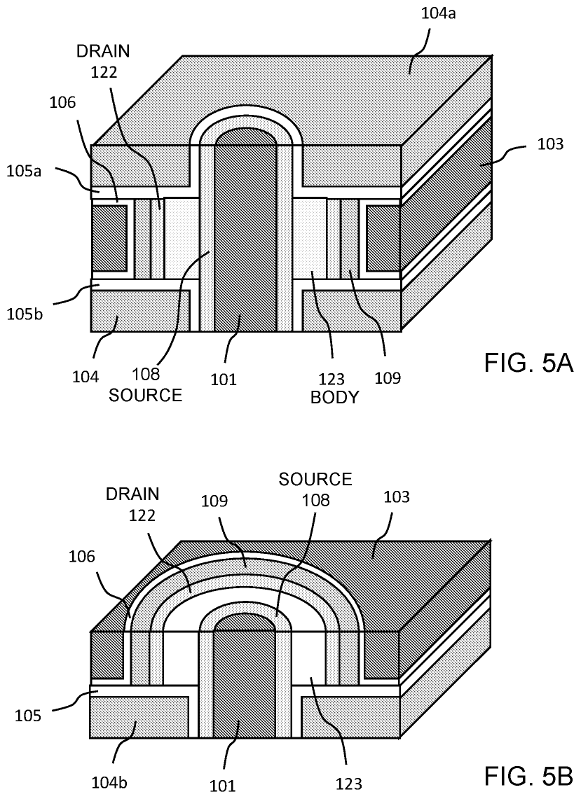

FIG. 5A shows another embodiment of a 3D cell structure according to the invention. This embodiment is similar to the embodiment shown in FIG. 1A except that the select transistor is formed as a conventional junction transistor instead of a thin-film transistor. The source 108 and drain 122 regions of the transistor are formed of heavily doped diffusion regions in a semiconductor material. A body 123 of the transistor is formed of lightly doped semiconductor material, such as lightly doped silicon material.

FIG. 5B shows the cell structure shown in FIG. 5A with the gate 104a and gate dielectric layer 105a removed to show the inner structure of the cell. The source 108 and drain 122 regions have the opposite type of doping as the body 123. For example, in one embodiment, the source 108 and drain 122 regions have N+ type of doping and the body 123 has P− type of doping. In another embodiment, the source 108 and drain 122 regions have P+ type of doping and the body 123 has N− type of doping.

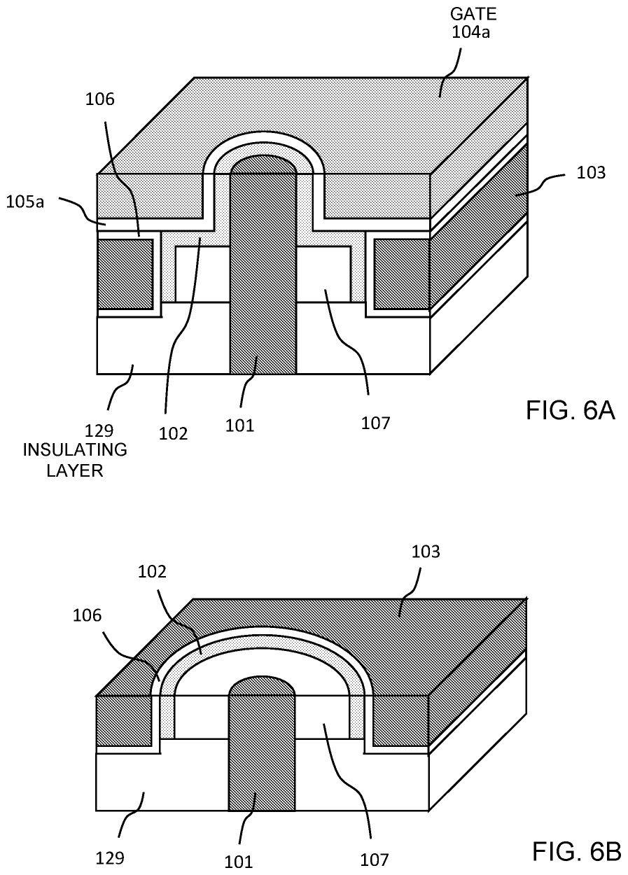

FIG. 6A shows another embodiment of a 3D cell structure according to the invention. This embodiment is similar to the embodiment shown in FIG. 1A except that one of the gates, such as gate 104b is eliminated and replaced with an insulating layer 129 that is formed of a material such as oxide. This forms a single-gate transistor.

FIG. 6B shows the cell structure shown in FIG. 6A with the gate 104a and gate dielectric layer 105a removed to show the inner structure of the cell.

In one embodiment, the bottom portion of the semiconductor layer 102 is etched by first removing the insulating layer 129 using an isotropic etching process, such as wet etching, and then applying an isotropic etching process, such as wet etching to etch the semiconductor layer 102. After that, an insulator such as oxide is deposited to re-form the insulating layer 129. It should be noted that this single-gate transistor structure can be applied to all the cell structures shown in other described embodiments herein with minor modifications. These modifications and variations are within the scope of invention.

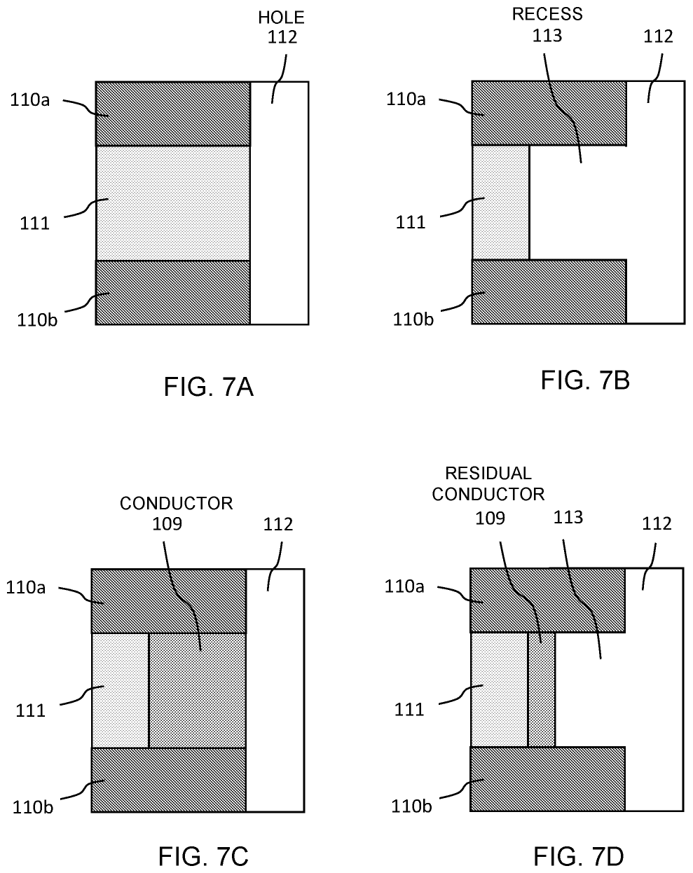

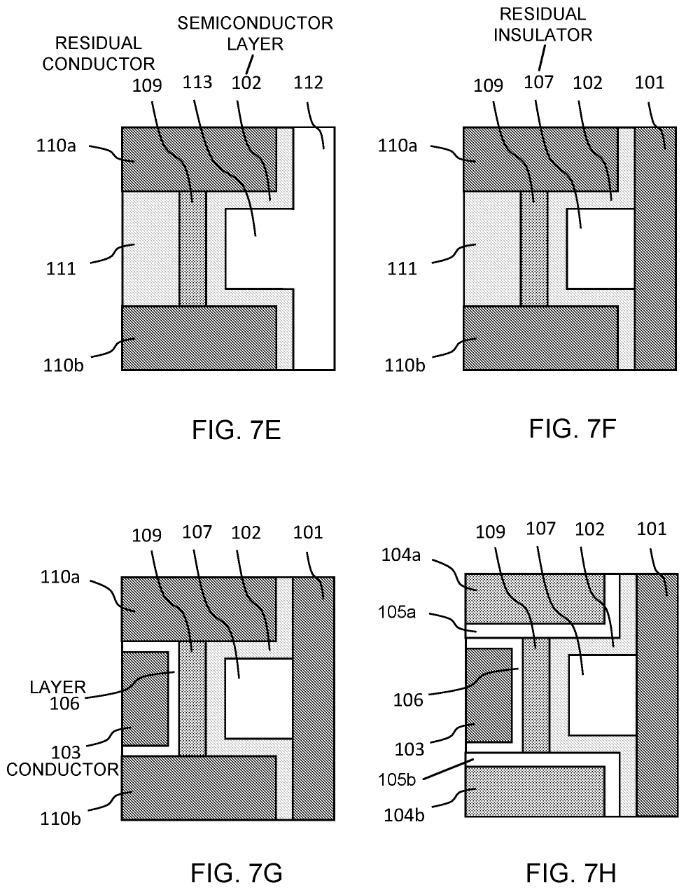

FIGS. 7A-H show embodiments of brief process steps configured to form 3D cell structures according to the invention. To illustrate the process steps, the cell structure shown in FIG. 3A is used as an example. It is obvious that the process steps may be applied to form the cell structures shown in other embodiments herein with minor modifications. These modifications and variations are within the scope of invention.

FIG. 7A illustrates how multiple first sacrificial layers, such as layers 110a and 110b and multiple second sacrificial layers, such as layer 111 are alternately deposited to form a stack. The first and second sacrificial layers have high etch selectivity. For example, in one embodiment, the first sacrificial layers 110a-b are nitride layers and the second sacrificial layer 111 is an oxide layer. After the stack is formed, multiple vertical bit line holes, such as hole (or opening) 112 are formed by using an anisotropic etching process, such as deep trench etching to etch through all the layers in the stack.

FIG. 7B illustrates how an isotropic etching process, such as wet etching is applied through the vertical bit line hole 112 to selectively etch the second sacrificial layer 111 to form a recess 113.

FIG. 7C illustrates a sequence of operations where the vertical bit line hole 112 and the recess 113 are filled with conductor material 109, such as metal or polysilicon material using a deposition process such as chemical vapor deposition (CVD). Next, the conductor material in the bit line hole 112 is etched by using an anisotropic etching process, such as dry etching, to form the residual conductor layer 109 inside the recess.

FIG. 7D illustrates how an isotropic etching process, such as wet etching is performed through the vertical bit line hole 112 to selectively etch the conductor 109 inside the recess 113 to form a residual of the conductor layer 109 as shown. It should be noted that in one embodiment, to form the cell structure shown in FIG. 1A, the process steps shown in FIGS. 7C-D may be skipped.

FIG. 7E illustrates how a semiconductor layer 102, such as a silicon layer or an indium gallium zinc oxide (IGZO) layer is formed on the surface of the sidewall of the vertical bit line hole 112 and the residual conductor 109 within recess 113 by using thin-film deposition or epitaxial deposition.

FIG. 7F illustrates a sequence of operations wherein the vertical bit line hole 112 and the recess 113 are filled with an insulator material 107, such as oxide material by using a deposition process. Next, an anisotropic etching process, such as dry etching is performed to etch the insulator 107 out of the vertical bit line hole 112 except for a residual of the insulator 107 inside the recess 113. Next, the vertical bit line hole 112 is filled with a conductor material, such as metal or polysilicon to form a vertical bit line 101.

FIG. 7G illustrates how the second sacrificial layer 111 is removed by using an isotropic etching process, such as wet etching. Next, the dielectric layer 106 is formed on the surface of the sidewalls of the first sacrificial layers 110a-b and the residual conductor 109 within the space previously occupied by the second sacrificial layer 111 by using a thin-film deposition process. Depending on the cell technology, the dielectric layer 106 can comprise multiple layers. In one embodiment, these multiple layers are formed by applying thin-film depositions multiple times. After depositing the dielectric layer 106, the space is filled with a conductor layer 103, such as a metal or polysilicon layer by using a deposition process such as chemical vapor deposition (CVD).

FIG. 7H illustrates a sequence of operations wherein the first sacrificial layers 110a and 110b are removed by using an isotropic etching process, such as wet etching. Next, gate dielectric layers 105a-b, comprising thin oxide or high-K material, are formed on the surface of the sidewall in the space previously occupied by the first sacrificial layers 110a-b by using a thin-film deposition process. Then, the spaces are filled with a conductor material, such as metal or polysilicon, to form the gates 104a-b. As a result, the cell structure shown in FIG. 3A is formed.

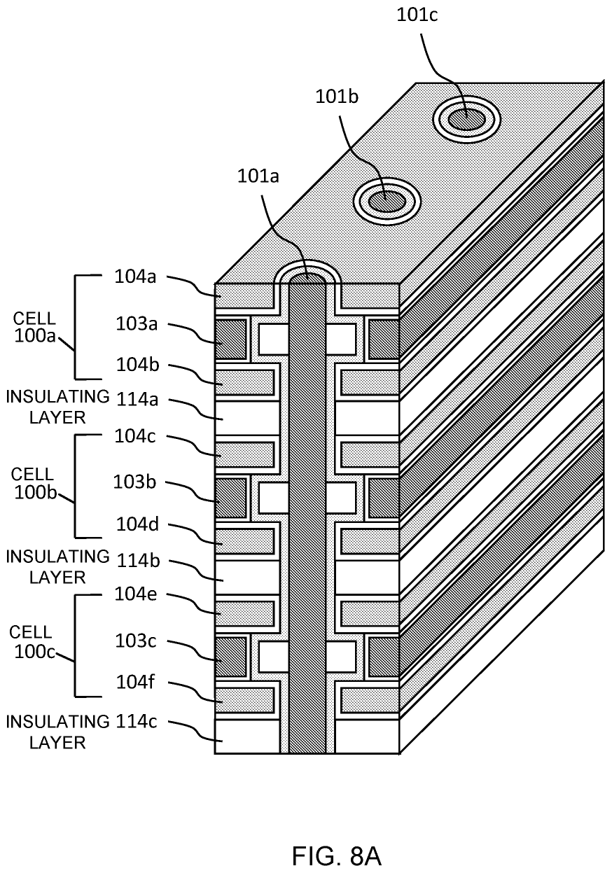

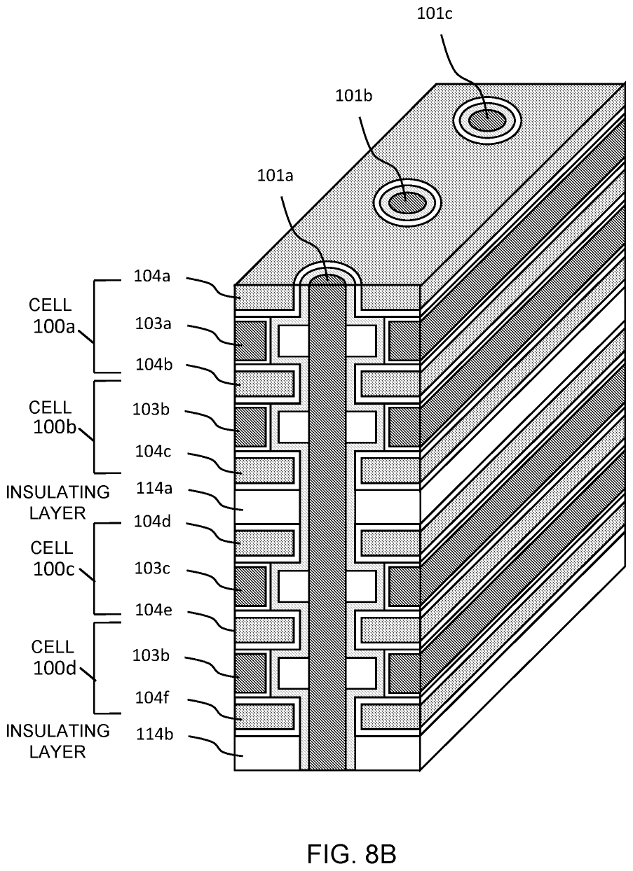

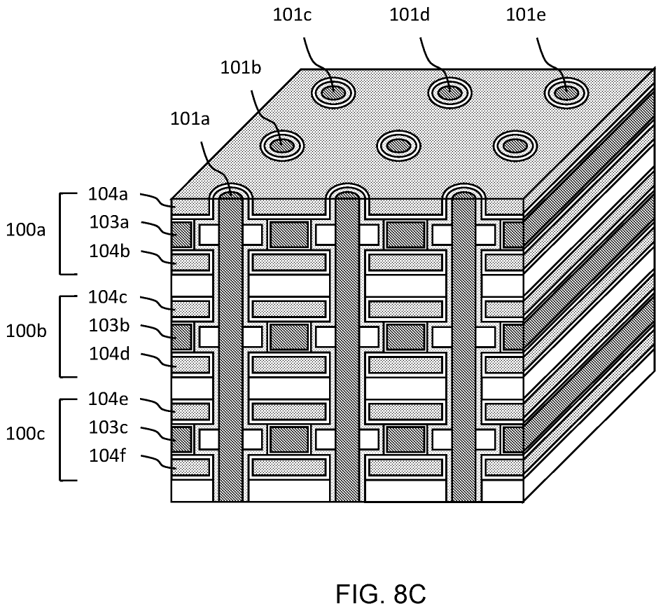

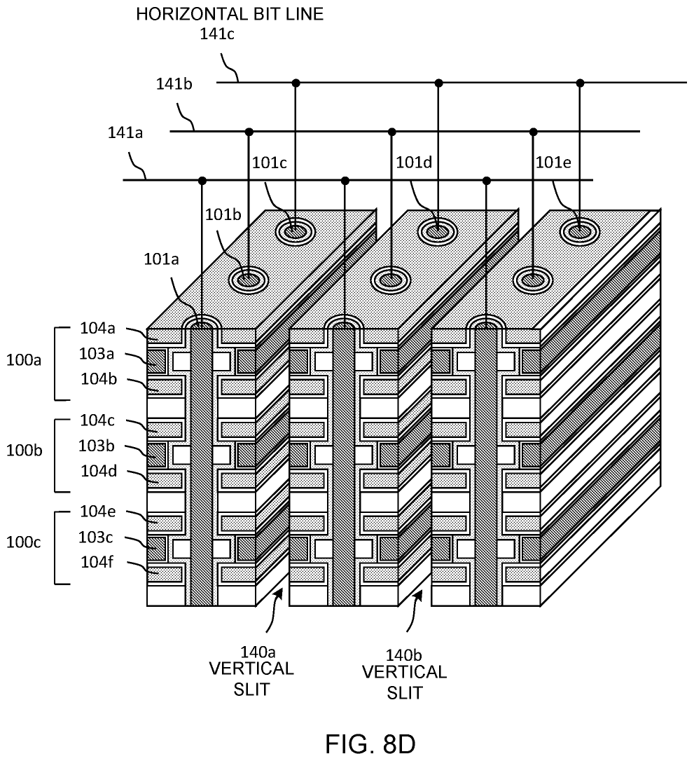

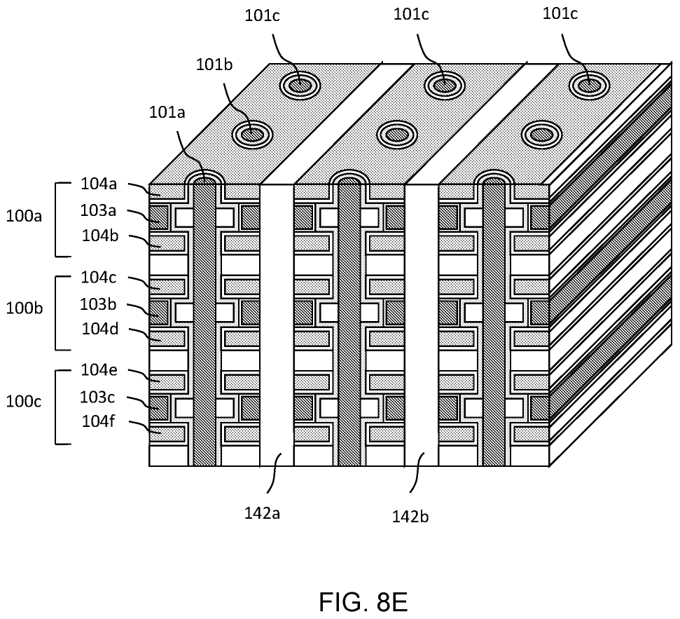

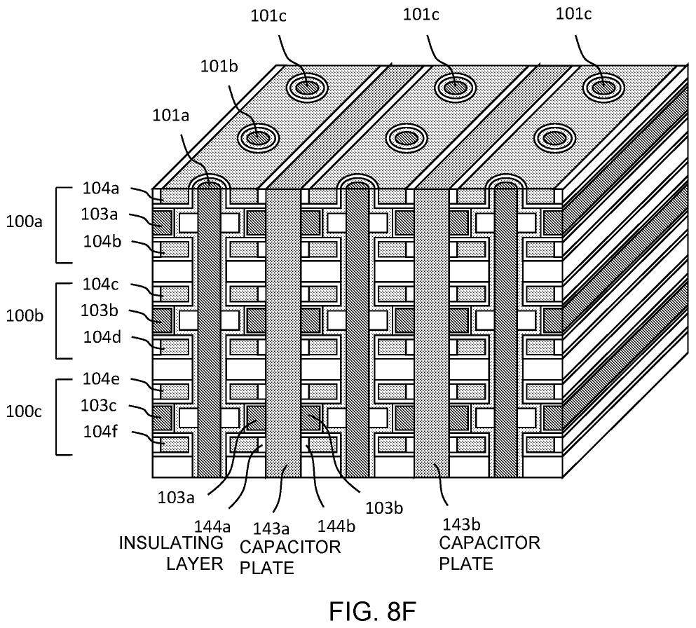

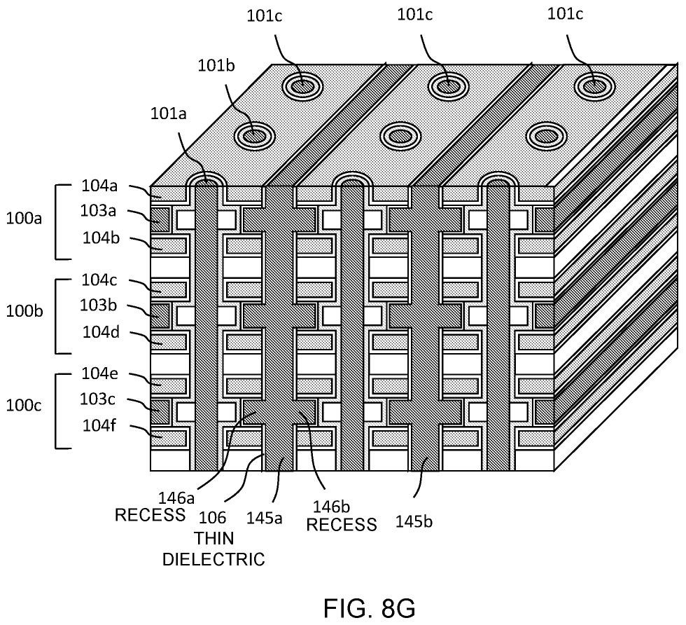

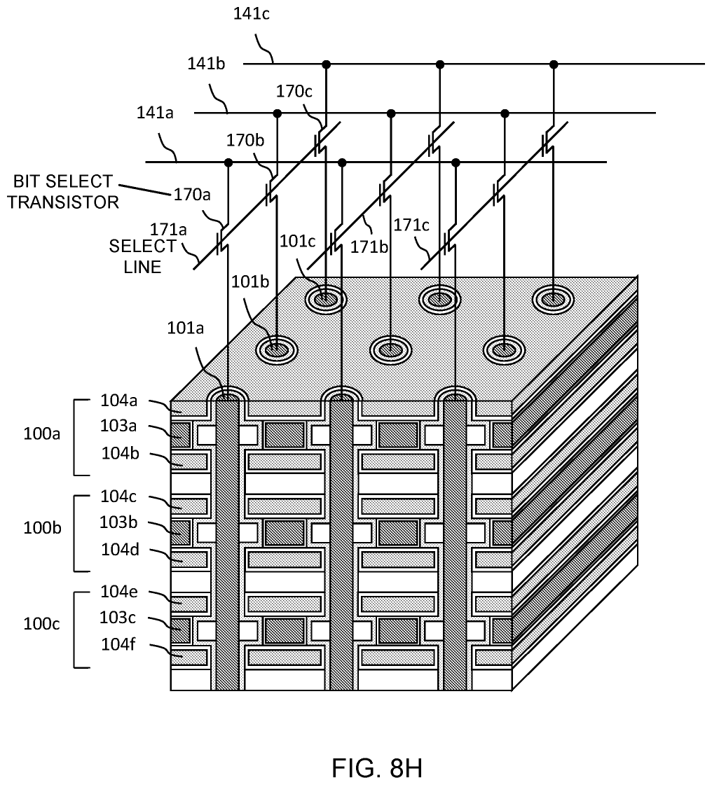

FIGS. 8A-G show embodiments of a 3D array structure according to the invention. The 3D array comprises the cell structure shown in FIG. 1A as an example. It should be noted that the 3D array structure can comprise any of the cell structures shown or described in other embodiments herein. These modifications and variations are within the scope of invention.

FIG. 8A illustrates how multiple cells, such as cells 100a to 100c are stacked to form a 3D array. The cells 100a to 100c are separated by insulating layers 114a to 114c that comprise material such as oxide or nitride. The array also comprises vertical bit lines 101a to 101c, word lines 104a to 104f, and conductor layers 103a to 103c. In this embodiment, each cell, such as 100a, can be selected by two word lines, such as word lines 104a and 104b, that are connected to each cell. In one embodiment, the two word lines connected to each cell, such as word lines 104a and 104b, are connected to different decoder signals. In another embodiment, the two word lines connected to each cell, such as word lines 104a and 104b, are connected to the same decoder signal.

FIG. 8B shows another embodiment of a 3D array structure according to the invention. This embodiment is similar to the embodiment shown in FIG. 8A except that two adjacent cells, such as cells 100a and 100b, share one word line 104b. Similarly, the adjacent cells 100c and 100d share the word line 104e. In one embodiment, this reduces the height of the 3D array structure. In this embodiment, the shared word lines 104b and 104e can be connected to ground or supplied with 0V to turn off the transistor between the two adjacent cells. The cells 100a and 100b are selected by the word lines 104a and 104c, respectively. The cells 100c and 100d are selected by the word lines 104d and 104f, respectively.

FIG. 8C shows another embodiment of a 3D array structure according to the invention. This embodiment is similar to the embodiment shown in FIG. 8A except that the word lines 104a to 104f are formed as layers instead of line patterns. In one embodiment, this reduces the die size by reducing the horizontal space between the word lines. Also shown in FIG. 8C are vertical bit lines 101a to 101e. In one embodiment, a bit line select transistor (as shown in FIGS. 8H-I) is located on top or at the bottom of the array and is connected to each bit line to enable selection of the bit lines.

The 3D array structure shown in FIG. 8C is suitable for FRAM, RRAM, PCM, and MRAM applications. However, it may not be suitable for DRAM application. Because DRAM cell's read operation is destructive, unselected cells coupled to a selected word line layer may be turned on and cause charge-sharing between the cell capacitors and the bit line capacitance and thus lose their data. Therefore, for DRAM application, the 3D array structure shown in FIG. 8D is provided.

FIG. 8D shows an embodiment of a 3D DRAM array structure according to the invention. In this embodiment, vertical slits, such as vertical slits 140a and 140b are formed by using an anisotropic etching process, such as deep trench etching to cut through all the layers. The slits 140a and 140b cut the word line layers into individual word lines, such as the individual word lines 104a to 104f.

The vertical bit lines, such as vertical bit lines 101a to 101c that are coupled to the same word lines, such as 104a to 104f are connected to different horizontal bit lines 141a to 141c. In one embodiment, the horizontal bit lines 141a to 141c are formed of conductor material, such as metal or polysilicon material. The horizontal bit lines 141a to 141b can be located on top of the 3D array as shown in FIG. 8D or located at the bottom of the 3D array. By using this array structure, all the cells selected by a word line will be coupled to the horizontal bit lines to perform read and write-back (refresh) operations. Therefore, the previously described data loss problem is eliminated.

FIG. 8E illustrates how the vertical slits 140a and 140b shown in FIG. 8D are filled with insulator material 142a-b, such oxide material, by using a deposition process such as chemical vapor deposition (CVD).

FIG. 8F illustrates how the vertical slits 140a and 140b shown in FIG. 8D are filled with conductor material, such as metal material to form vertical capacitor plates 143a and 143b. The capacitor plates 143a and 143b are connected to the conductor layers, such as layers 103a and 103b of the cells. In one embodiment, the capacitor plates 143a and 143b are connected to a constant voltage, such as VDD or ground.

In one embodiment, insulating layers, such as insulating layers 144a and 144b are formed on the sidewalls of the word lines, such as word lines 104a to 104f, prior to forming the capacitor plates to prevent the word lines from shorting to the vertical capacitor plates 143a and 143b. In one embodiment, the insulating layers 144a and 144b are formed by using an isotropic etching process, such as wet etching to etch the word line layers 104a to 104f through the vertical slits 140a and 140b to form recesses in the word lines. Next, the recesses are filled with insulator, such as an oxide insulator to form the insulating layers 144a and 144b.

In another embodiment, the insulating layers 144a and 144b are formed by applying a metal-oxidation process through the vertical slits 140a and 140b to form a metal-oxide layer on the sidewalls of the word lines 104a to 104f. Next, the vertical slits 140a and 140b are filled with conductor material, such as metal material to form the capacitor plates 143a and 143b.

FIG. 8G shows another embodiment of a 3D DRAM array structure according to the invention. In this embodiment, the conductor layer 103 of the cell structure shown in FIG. 1A is formed of a sacrificial material, such as a nitride material that has high etch selectively from the word lines 104a and 104b. After the vertical slits 140a and 140b shown in FIG. 8D are formed, an isotropic etching process, such as wet etching is performed through the vertical slits 140a and 140b to etch the sacrificial layers to form recesses, such as recesses 146a and 146b.

Next, a thin dielectric layer 106 comprising material such as thin oxide material or high-K material such as HfO2, is formed on the surface of the sidewalls of the vertical slits 140a and 140b and the recess areas 146a and 146b by using a thin-film deposition process. Next, the slits 140a and 140b and the recess areas 146a and 146b are filled with conductor material, such as metal material by using a metal deposition process to form the capacitor plates 145a and 145b.

FIG. 8H shows another embodiment of a 3D DRAM array structure using the array structure shown in FIG. 8C according to the invention. The vertical bit lines, such as bit lines 101a to 101c, are connected to horizontal bit lines 141a to 141c through bit line select transistors 170a to 170c. Select lines 171a to 171c are connected to the gates of the select transistors, such as select transistors 170a to 170c. In one embodiment, the bit line select transistors 170a to 170c are formed of vertical-channel transistors or any other suitable type of transistors.

FIG. 8I shows an embodiment that uses vertical-channel transistors as the bit line select transistors, such as bit line select transistor 170a. The bit line select transistor 170a is connected to the horizontal bit line 141a through a conductor contact 172.

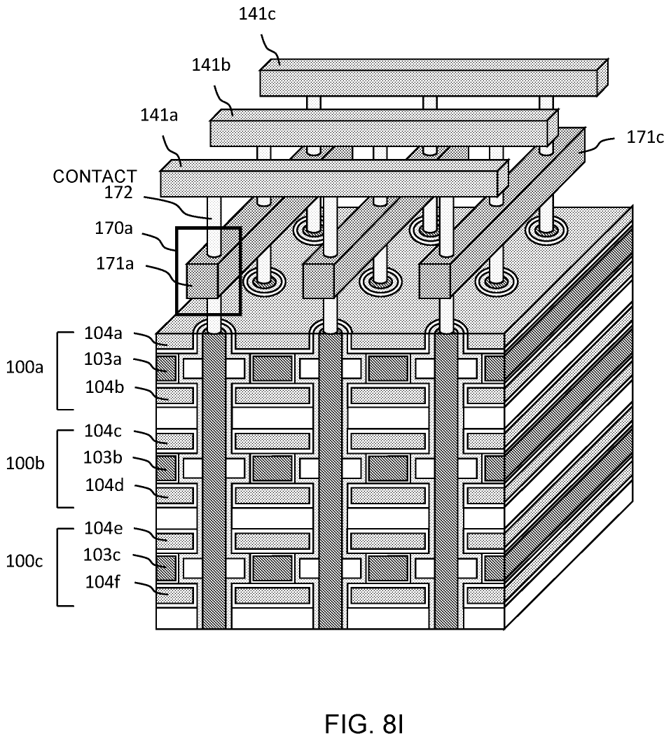

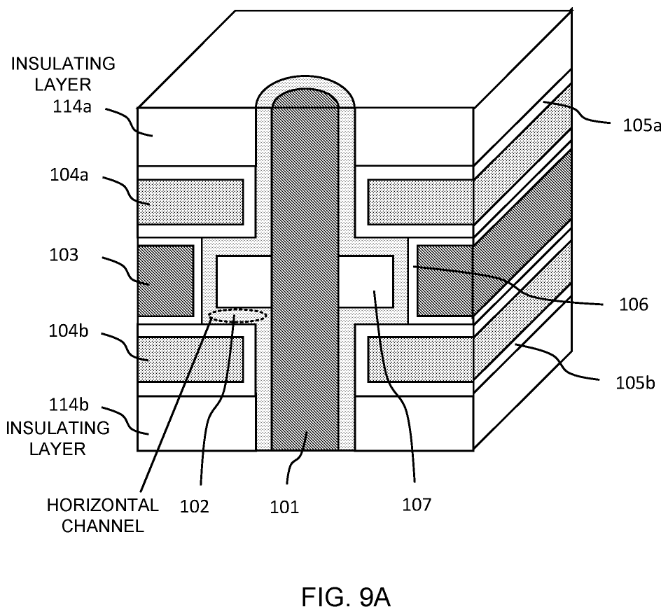

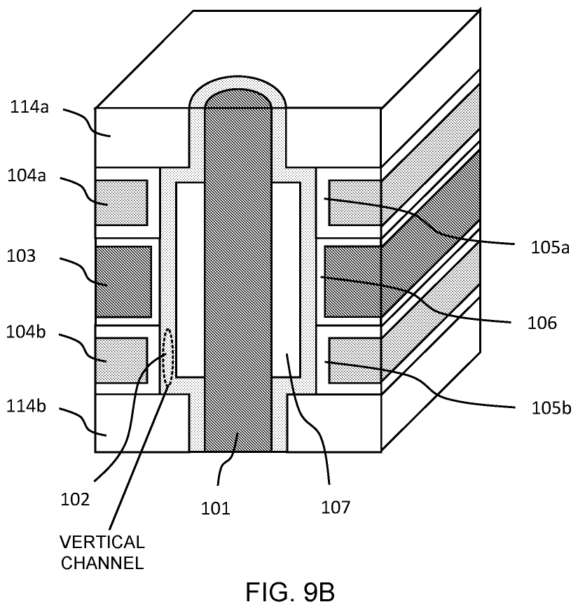

FIG. 9A shows an embodiment of a 3D cell structure according to the invention. This embodiment is similar to the embodiment shown in FIG. 1A except that this embodiment includes insulating layers 114a and 114b between the different layers of cells. In this embodiment, the channel of the select transistor is located in a horizontal direction, as shown by the indicator within the semiconductor layer 102.

FIG. 9B shows another embodiment of a 3D cell structure according to the invention. This embodiment is similar to the embodiment shown in FIG. 9A except that the channel of the select transistor is located in a vertical direction, as shown by the indicator within the semiconductor layer 102. This transistor structure can be applied to all the cell structures herein shown in other embodiments. These modifications and variations are within the scope of invention.

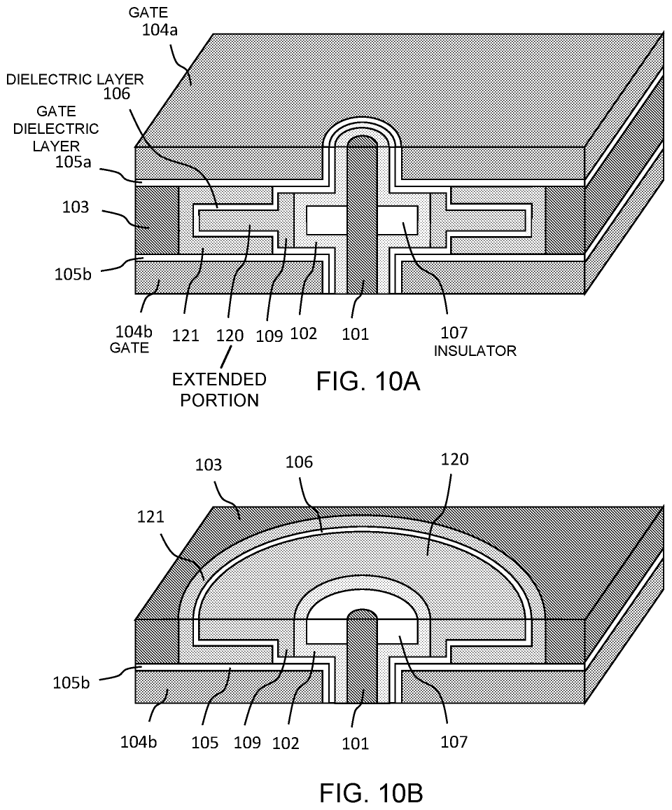

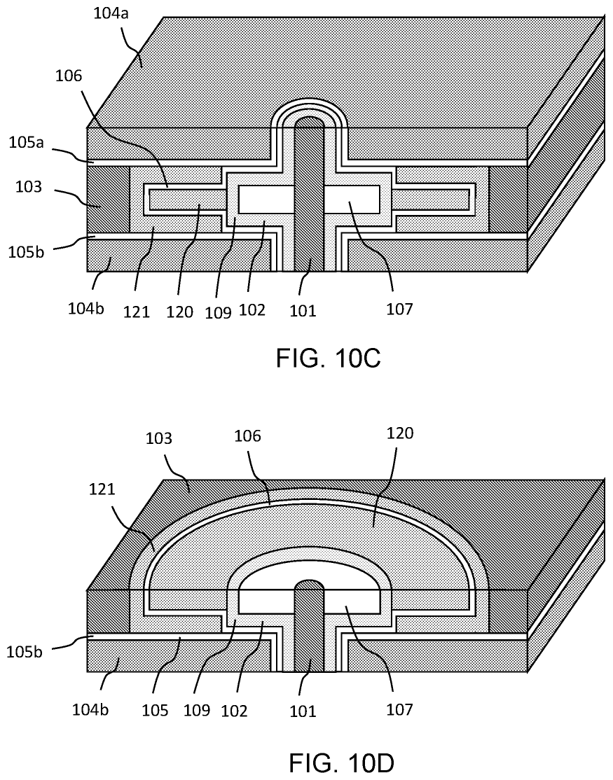

FIG. 10A shows another embodiment of a 3D cell structure according to the invention. This embodiment is similar to the embodiment shown in FIG. 3A except that an extended portion 120 of the conductor layer 109 is added to increase the value of the capacitor. In one embodiment, the extended portion 120 is formed of a conductor material, such as metal or polysilicon material. The extended portion 120 is coupled to the conductor layer 121, which is formed of a material such as metal or polysilicon. The conductor layer 121 is also connected to the conductor layer 103.

FIG. 10B shows the cell structure shown in FIG. 10A with the gate 104a and gate dielectric layer 105a removed to show the inner structure of the cell.

In an embodiment, the cell structure shown in FIGS. 10A-B comprises the vertical bit line 101, the insulator 107 surrounding a first portion of vertical bit line 101, the continuous semiconductor layer 102 surrounding the insulator 107 and a second portion of the vertical bit line 101, the extended portion 120 of conductor material surrounding the continuous semiconductor layer 102, and the dielectric layer 106 surrounding extended portion of conductor material 120. The cell structure also comprises the conductor layer 121 surrounding the dielectric layer 106, the conductor layer 103 surrounding the conductor layer 121, the dielectric layer 105a on a top surface of the conductor layer 121 and conductor layer 103, the dielectric layer 105b on a bottom surface of the conductor layer 121 and conductor layer 103, the gate 104a on a top surface of the dielectric layer 105a, and the gate 104b on a bottom surface of the dielectric layer 105b.

FIG. 10C shows another embodiment of a 3D cell structure according to the invention. This embodiment is similar to the embodiment shown in FIG. 10A except that the extended portion 120 is formed to have a shape that is different than the shape shown in FIG. 10A. In this embodiment, the extended portion 120 is located completely inside the glove formed by the conductor layer 121.

FIG. 10D shows the cell structure shown in FIG. 10C with the gate 104a and gate dielectric layer 105a removed to show the inner structure of the cell.

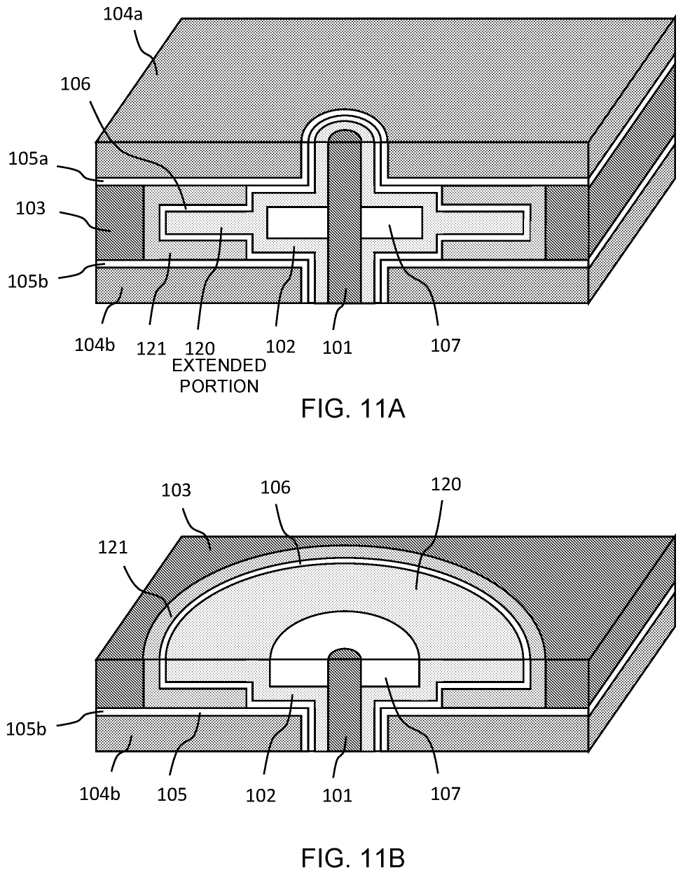

FIG. 11A shows another embodiment of a 3D cell structure according to the invention. This embodiment is similar to the embodiment shown in FIGS. 10A-B except that the extend portion 120 is formed by the extension of the semiconductor layer 102.

FIG. 11B shows the cell structure shown in FIG. 11A with the gate 104a and gate dielectric layer 105a removed to show the inner structure of the cell.

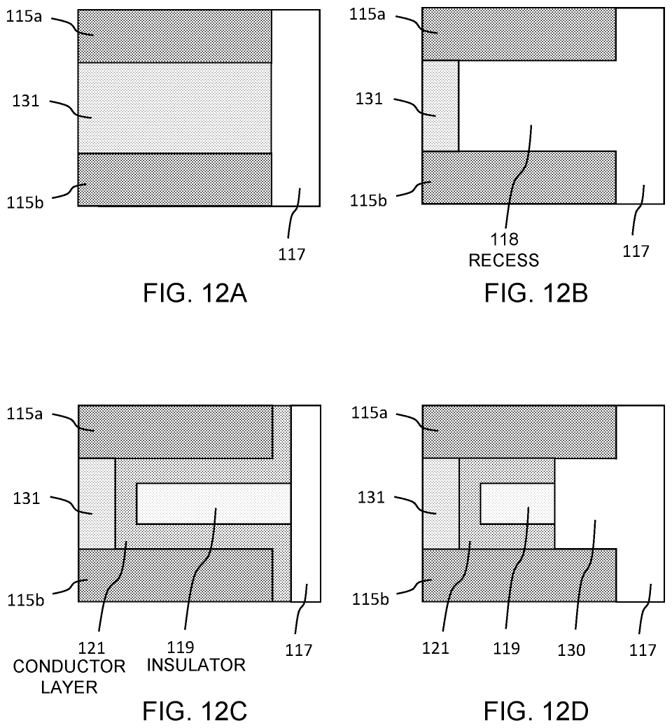

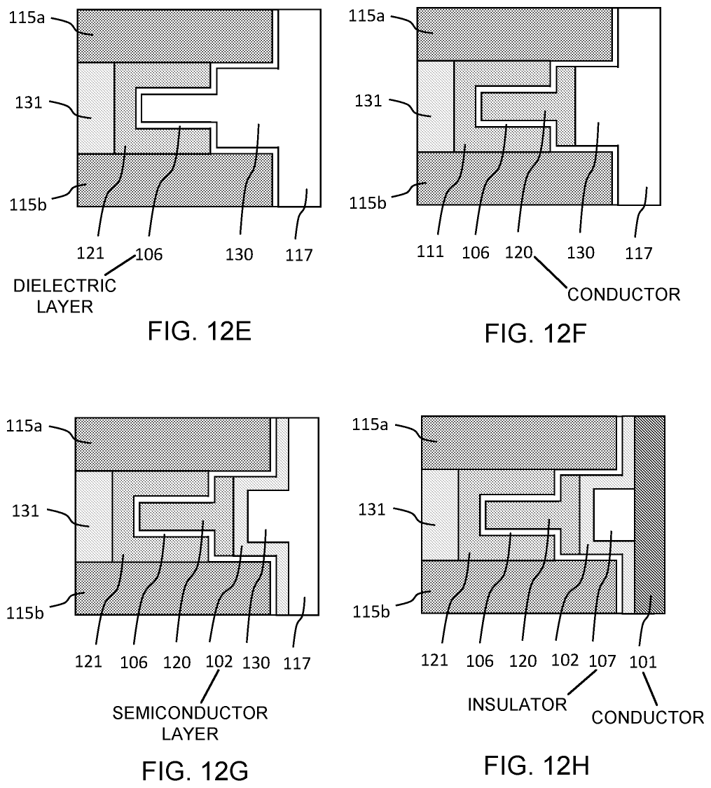

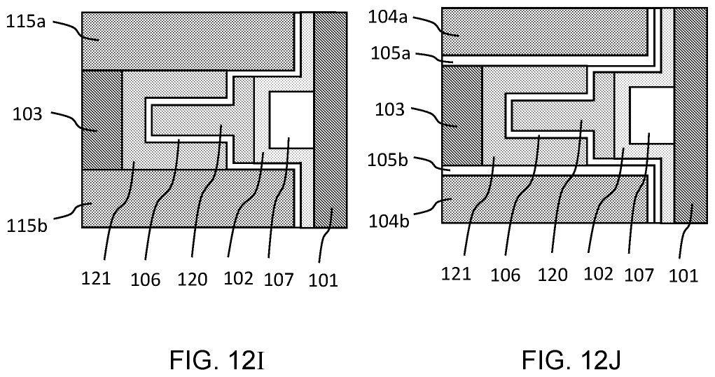

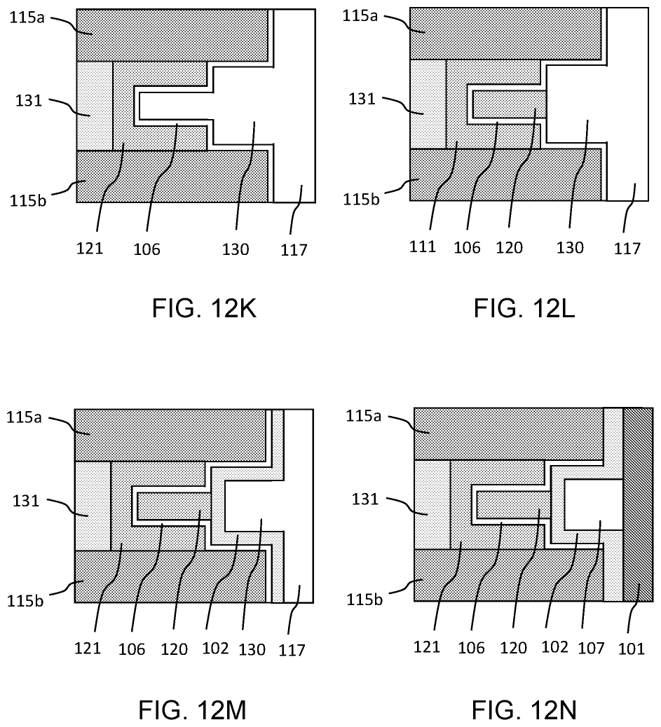

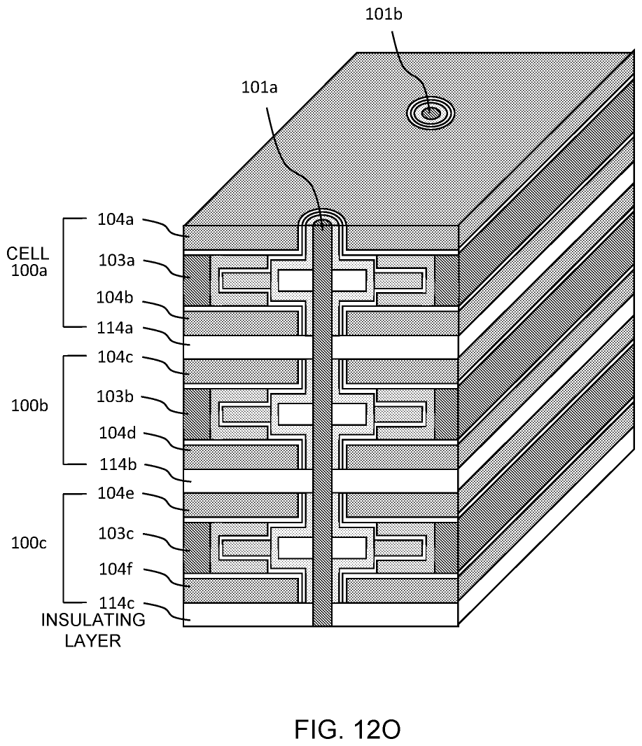

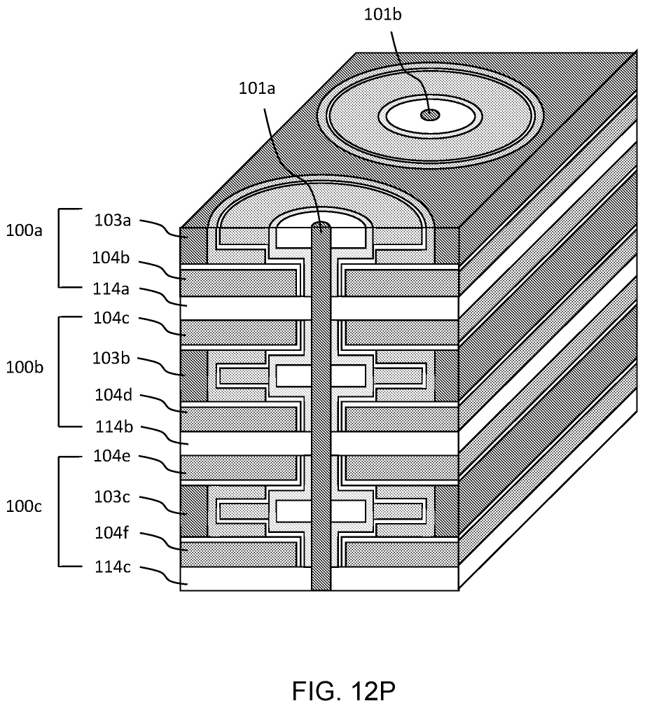

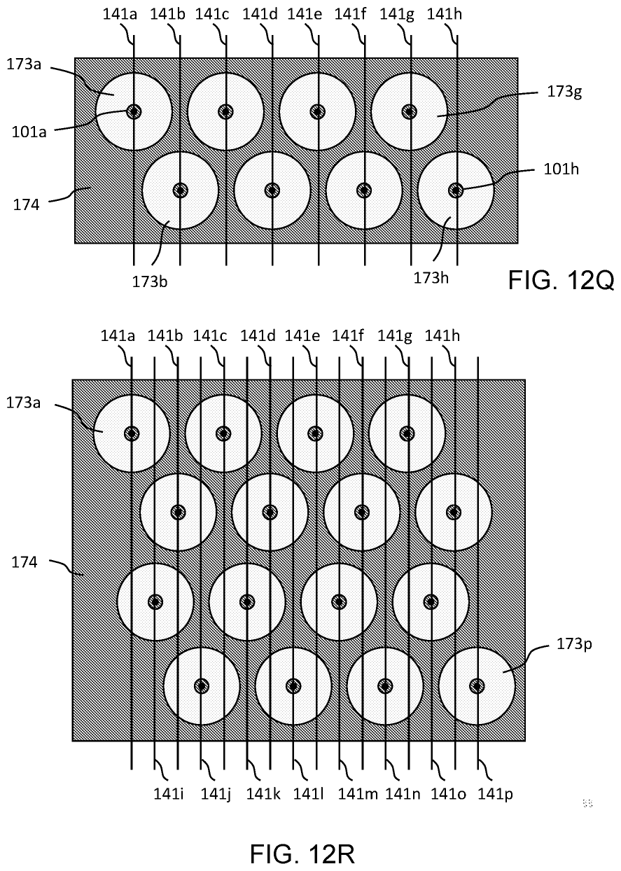

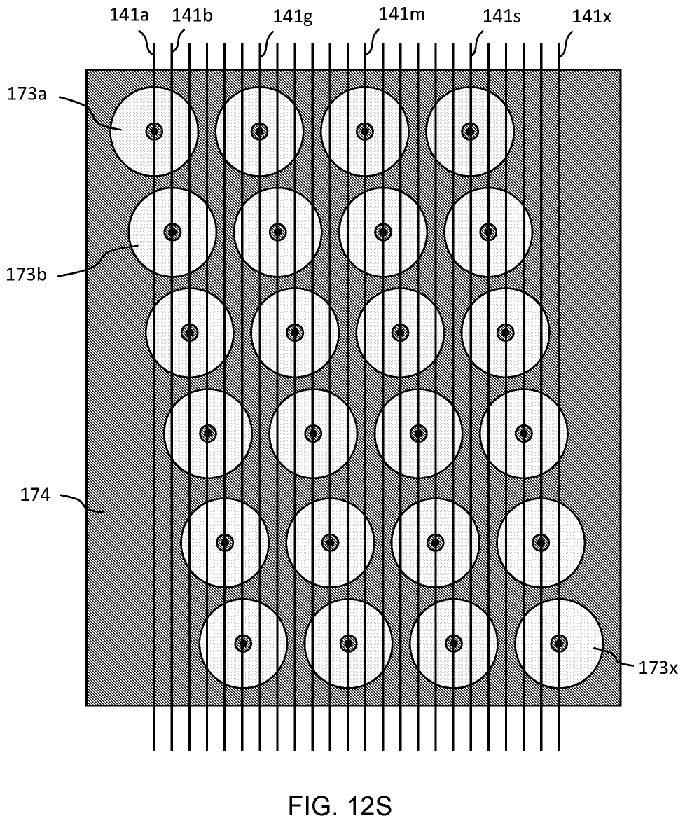

FIGS. 12A-J show embodiments of brief process steps configured to form the 3D cell structure shown in FIG. 10A.

FIG. 12A illustrates how multiple first sacrificial layers 115a and 115b comprising material such as nitride and multiple second sacrificial layers 131 comprising material such as oxide are alternately deposited to form a stack. The first sacrificial layers 115a and 115b and the second sacrificial layer 131 have high etch selectivity. Next, multiple vertical bit line holes, such as bit line hole (or opening) 117 are formed by using an anisotropic etching process, such as deep trench etching, to etch through all the layers of the stack.

FIG. 12B illustrates how an isotropic etching process, such as wet etching, is performed through the vertical bit line hole 117 to selectively etch the second sacrificial layer 131 to form a recess 118.

FIG. 12C illustrates how a conductor layer 121 is formed on the surface of the sidewalls of the second sacrificial layer 131 and the first sacrificial layers 115a-b within the recess 118 by using a thin-film deposition process. Next, the vertical bit line hole 117 and the recess 118 are filled with an insulator 119, such as oxide or nitride material using a deposition process. Then, an anisotropic etching process, such as dry etching, is performed to etch the conductor 121 to restore the bit line hole 117.

FIG. 12D illustrates how an isotropic etching process, such as wet etching, is performed through the vertical bit line hole 117 to selectively etch the conductor layer 121 and the insulator 119 to form the extended recess 130 as shown. In another embodiment, the structure shown in FIG. 12D is formed by using two separated isotropic etching processes. A first isotropic etching process is performed to etch only the insulator 119. Next, a second isotropic etching process is performed to etch the conductor layer 121 using the insulator 119 as a hard mask.

FIG. 12E illustrates how an isotropic etching process, such as wet etching, is performed to remove the insulator 119. Next, a thin dielectric layer 106, such as thin oxide or high-K material is formed on the surface of the sidewall of the vertical bit line hole 117 and the recess 130 by using a thin-film deposition process such as atomic layer deposition (ALD).

FIG. 12F illustrates a sequence of step in which a conductor material 120, such as metal or polysilicon material, is deposited to fill the vertical bit line hole 117 and the recess 130. Next, an anisotropic etching process, such as dry etching, is performed to etch the conductor 120 in the vertical bit line hole 117 leaving a residual of the conductor 120 inside the recess. Next, an isotropic etching process, such as wet etching, is performed through the vertical bit line hole 117 to selectively etch the conductor layer 120 to form the partial recess 130. The residual of the conductor layer 120 forms the extended portion 120 shown in FIG. 10A. For the cell structure shown in FIGS. 11A-B, the process steps shown in FIG. 12F can be skipped.

FIG. 12G illustrates how a semiconductor layer 102, comprising material such as silicon, polysilicon, or indium gallium zinc oxide (IGZO) material is formed on the surface of the sidewall of the dielectric layer 106 and the conductor 120 by using thin-film deposition such as atomic layer deposition (ALD), epitaxial growth or epitaxial deposition through the bit line hole 117.

FIG. 12H illustrates a sequence of steps in which the vertical bit line hole 117 and the recess 130 are filled with an insulator material 107, such as oxide material, by using a deposition process such as CVD through the bit line hole 117. Next, an anisotropic etching process, such as dry etching is performed to etch the insulator 107 in the vertical bit line hole 117 leaving a residual of the insulator 107 inside the recess 130. Next, the vertical bit line hole 117 is filled with a conductor material 101, such as metal or polysilicon material, to form a vertical bit line 101.

FIG. 12I illustrates how the second sacrificial layer 131 shown in FIG. 12H is removed by using an isotropic etching process, such as wet etching. Then, the resulting space is filled with a conductor material, such as metal or polysilicon, to form a conductor layer 103.

FIG. 12J illustrates how the first sacrificial layers 115a and 115b are removed by using an isotropic etching process, such as wet etching. Gate dielectric layers 105a and 105b comprising material such as thin oxide or high-K material is formed on the surface of the sidewall in the space previously occupied by the first sacrificial layers 115a and 115b by using a thin-film deposition process. Next, the spaces are filled with a conductor material, such as metal or polysilicon material, to form the gates 104a and 104b. As a result, the cell structure shown in FIG. 10A is formed.

FIGS. 12K-N show embodiments of brief process steps configured to form the 3D cell structure shown in FIG. 10C.

FIG. 12K shows the cell structure formed after performing the process steps shown in FIG. 12E. The reader is referred to FIGS. 12A-E for the detailed descriptions of the process steps performed to form the cell structure shown in FIG. 12E.

FIG. 12L illustrates a sequence of process steps in which a conductor material 120, such as metal or polysilicon material, is deposited to fill the vertical bit line hole 117 and the recess 130. Next, an anisotropic etching process, such as dry etching, is performed to etch the conductor 120 in the vertical bit line hole 117 and the conductor 120 inside the recess. Next, an isotropic etching process, such as wet etching, is performed through the vertical bit line hole 117 to selectively etch the conductor layer 120 to form the recess 130. The residual of the conductor layer 120 forms the extended portion 120 shown in FIG. 10A. It should be noted that the shape of the conductor layer 120 is different from the one shown in FIG. 12F.

FIG. 12M illustrates how a semiconductor layer 102 comprising material such as silicon or indium gallium zinc oxide (IGZO) is formed on the surface of the dielectric layer 106 and the sidewall of the conductor 120 by using thin-film deposition or epitaxial deposition.

FIG. 12N illustrates a sequence of steps in which the vertical bit line hole 117 and the recess 130 are filled with an insulator material 107 such as oxide material by performing a deposition process through the bit line hole 117. Next, an anisotropic etching process, such as dry etching, is performed to etch the insulator 107 in the vertical bit line hole 117 except a residual of the insulator 107 inside the recess 130. Next, the vertical bit line hole 117 is filled with a conductor material, such as metal or polysilicon material, to form a vertical bit line 101. Next, the process steps shown in FIGS. 12I-J are performed to form the cell structure shown in FIG. 10C.

FIG. 12O shows another embodiment of a 3D array structure according to the invention. This embodiment is similar to the embodiment shown in FIG. 8A except that it uses the cell structure shown in FIG. 10C as an example. It should be noted that all the cell structures shown in other embodiments herein can also be applied to all the 3D array structures shown in FIGS. 8A-I.

The embodiment shown in FIG. 12O illustrates how multiple cells, such as cells 100a to 100c are stacked to form a 3D array. The cells 100a to 100c are separated by insulating layers 114a to 114c comprising material such as oxide or nitride. The array also includes vertical bit lines 101a to 101c, word lines 104a to 104f, and conductor layers 103a to 103c.

FIG. 12P shows the 3D array structure shown in FIG. 12O with the top word line 104a and partial layers removed to reveal the inner structure of the array.

FIG. 12Q shows an embodiment of a top view of the 3D array structure shown in FIGS. 12O-P according to the invention. FIG. 12Q illustrates cells 173a to 173h, vertical bit lines 101a to 101h, and horizontal bit lines 141a to 141h. The layer 174 can be either a word line or a select line of the bit line select transistor, depending on the type of the 3D array structure. For example, when using the 3D array structure shown in FIG. 8D, the layer 174 forms a word line, such as word line 104a. When using the 3D array structure shown in FIGS. 8H-I, the layer 174 forms a select line, such as select line 171a. In one embodiment, the first row of cells 173a to 173g and the second row of cells 172b to 173h are staggered as shown. This enables two rows of cells to be connected to one word line or select line 174.

FIG. 12R shows another embodiment of a top view of the 3D array structure shown in FIGS. 12O-P according to the invention. This embodiment is similar to the embodiment shown in FIG. 12Q except that four rows of the cells, such as cells 173a to 173p, are staggered as shown. This enables the four rows of cells 173a to 173p to be connected to one word line or select line 174. This embodiment doubles the number of the horizontal bit lines 141a to 141p compared with the embodiment shown in FIG. 12Q. This increases the ‘page’ size used in read and write operations to enhance the memory performance.

FIG. 12S shows a top view of another embodiment of the 3D array structure shown in FIGS. 12O-P according to the invention. This embodiment is similar to the embodiment shown in FIG. 12Q except that six rows of the cells 173a to 173x are staggered as shown. This enables the six rows of cells 173a to 173x to be connected to one word line or select line 174. This embodiment triples the number of the horizontal bit lines 141a to 141x compared with the embodiment shown in FIG. 12Q. This increases the ‘page’ size used in read and write operations to enhance the memory performance.

The embodiments shown in FIGS. 12Q-S are exemplary and not limiting. In other embodiments, the cells are staggered with any other number of rows or staggered in any other way. These variations and modifications are within the scope of the invention.

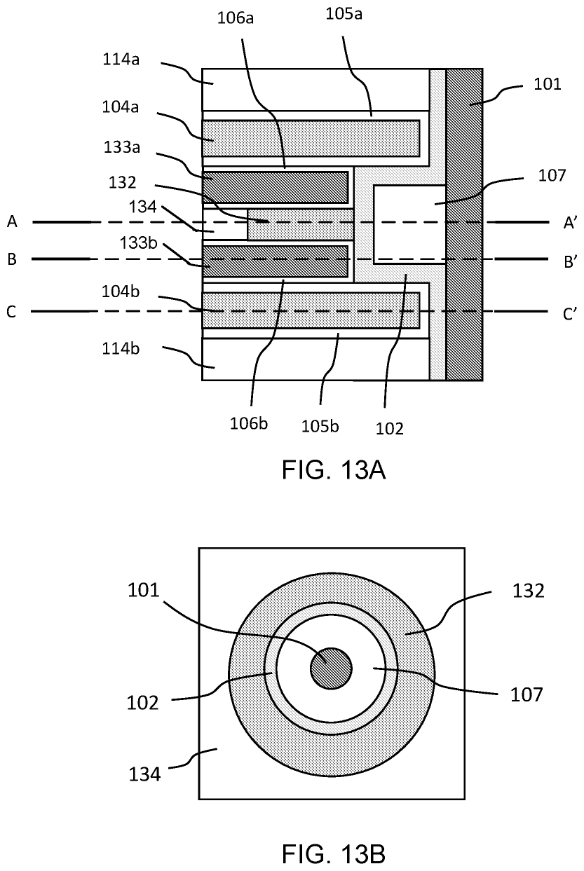

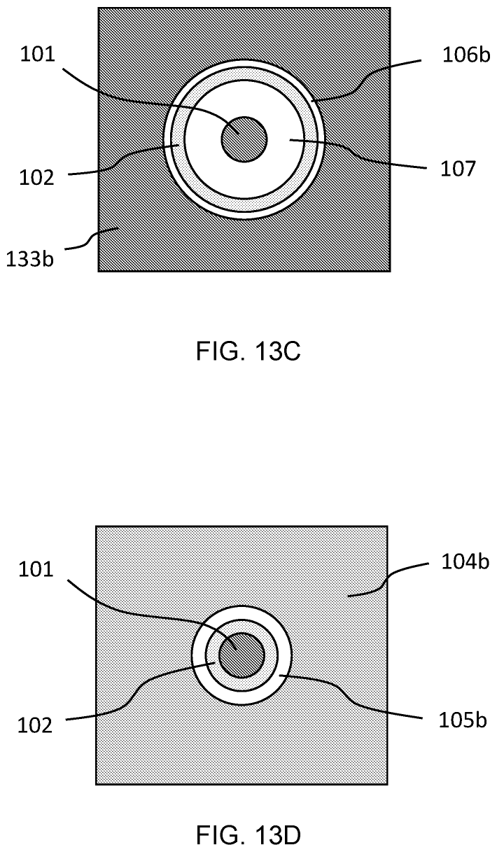

FIGS. 13A-D show embodiments of a 3D cell structure according to the invention.

FIG. 13A shows a side view of a 3D cell structure. This embodiment of the 3D cell structure is similar to the embodiment shown in FIGS. 10A-B except that the conductor layer 121 shown in FIGS. 10A-B is divided into two conductor layers 133a and 133b that are formed of metal or polysilicon material. The conductor plate 132 is formed of metal or polysilicon material and is connected to the semiconductor layer 102. Capacitor dielectric layers 106a and 106b comprise material such as thin oxide or high-K material (such as HfO2). An insulating layer 134 comprises material such as oxide or nitride material. The conductor layers 133a and 133b, the capacitor dielectric layers 106a and 106b, and the conductor plate 132 form a capacitor.

The array also includes a vertical bit line 101 and gates 104a and 104b formed of conductor material, such as metal or polysilicon material. The array also includes gate dielectric layers 105a and 105b that comprise material such as thin oxide or high-K material, such as hafnium oxide (HfO2). The array also includes a semiconductor layer 102 that comprises material such as silicon or indium gallium zinc oxide (IGZO). The array also includes an insulator 107 that comprises material such as oxide or nitride material. The array also includes insulating layers 114a and 114b that comprise material such as oxide or nitride material. In an embodiment, the gates 104a and 104b, gate dielectric layers 105a and 105b, and the semiconductor layer 102 form two thin film select transistors.

FIGS. 13B-D show top views of cross-sections of the 3D cell structure taken along lines A-A′, B-B′, and C-C′ as shown in FIG. 13A, respectively. It should be noted that the side view shown in FIG. 13A illustrates one half of the cell with the bit line 101 at the right. The top views shown in FIGS. 13B-D illustrate the entire cell with the bit line 101 in the center.

FIGS. 14A-B show an embodiment of a 3D cell structure according to the invention. This embodiment is similar to the embodiments shown in FIGS. 13A-D except that the conductor layers 133a and 133b are replaced with a conductor layer 135. The conductor layer 135 is formed using an isotropic etching process, such as wet etching, to remove the layers 133a, 133b and 134, and then forming a capacitor dielectric layer 106 using thin-film deposition and a conductor layer 135 using a deposition process.

FIG. 14B shows a top view of a cross-section taken line A-A′ shown in FIG. 14A. The cross-section views along lines B-B′ and C-C′ in FIG. 14A are the same as the ones shown in FIGS. 13B-C. It should be noted that the side view shown in FIG. 14A illustrates one half of the cell with the bit line 101 at the right. The top view shown in FIG. 14B illustrates the entire cell with the bit line 101 in the center. It should be noted that the cell structures shown in FIG. 13A and FIG. 14A can be applied to all the other embodiments of the cell structures shown herein according to the invention.

In one embodiment, the cell structure shown in FIGS. 14A-B comprises the vertical bit line 101, the insulator 107 surrounding a first portion of the vertical bit line 101, the continuous semiconductor layer 102 surrounding the insulator 107 and a second portion of the vertical bit line 101, the extended portion of conductor material 132 surrounding a first portion of a side surface of the continuous semiconductor layer 102, the dielectric layer 106 surrounding the extended portion of conductor material 132 and a second portion of the side surface of the continuous semiconductor layer 102, and the conductor layer 135 surrounding the first dielectric layer. The cell structure also comprises the dielectric layer 105a above a top surface of the conductor layer 135, the dielectric layer 105b below a bottom surface of the conductor layer 135, the conductor layer 104a on a top surface of the dielectric layer 105a, and the conductor layer 104b on a bottom surface of the dielectric layer 105b.

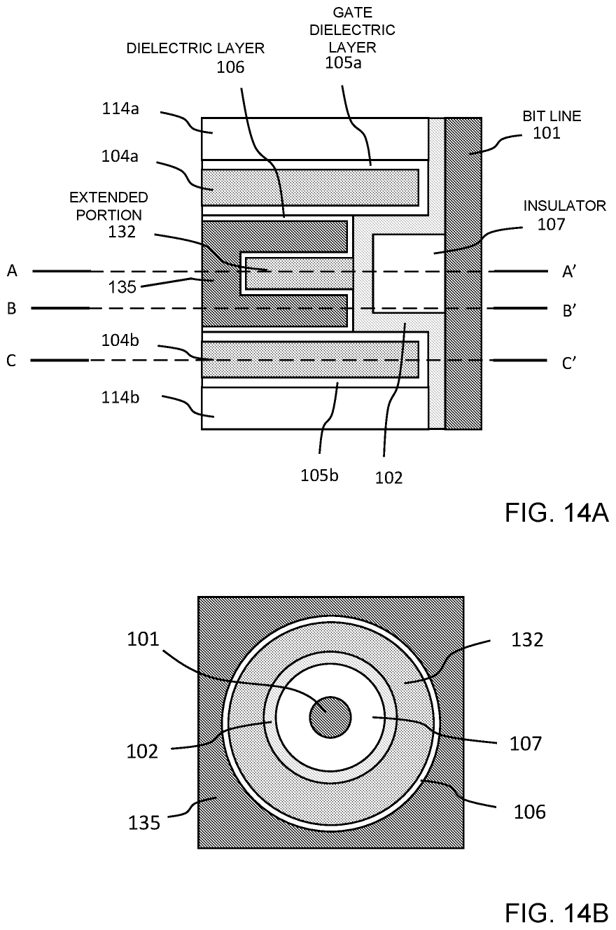

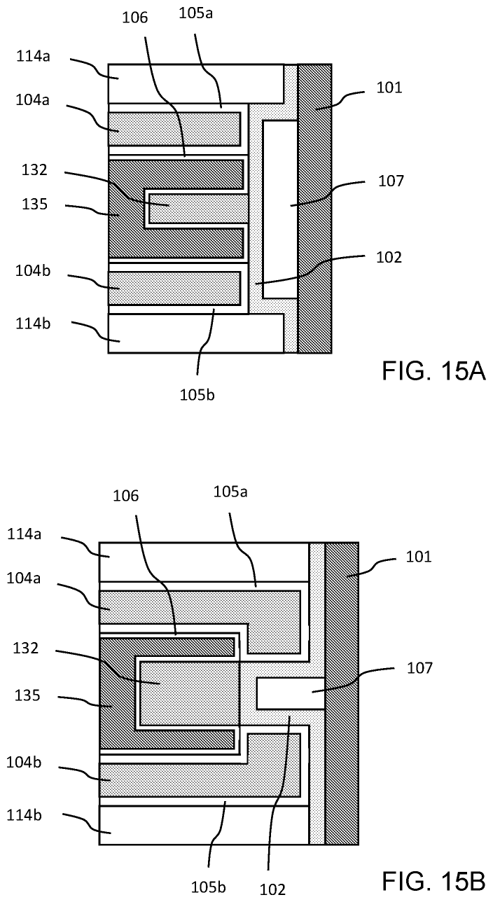

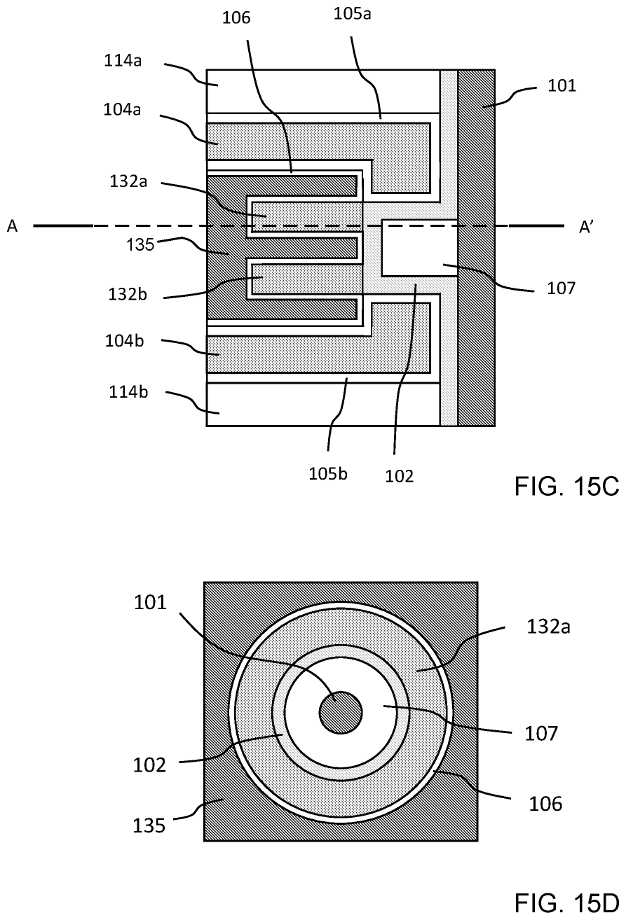

FIG. 15A shows a side view of another embodiment of a 3D cell structure according to the invention. This embodiment is similar to the embodiment shown in FIG. 14A except that the gates 104a and 104b are formed to have different shapes. In this embodiment, the channel of the select transistors as shown by the indicator 102 is located in the vertical direction, while the channel of the select transistors in FIG. 14A is located in the horizon direction.

FIG. 15B shows a side view of another embodiment of a 3D cell structure according to the invention. This embodiment is similar to the embodiment shown in FIG. 14A except that the gates 104a and 104b are formed to have different shapes. In this embodiment, the channel of the select transistors as shown by the indicator 102 is located in a horizontal direction.

It should be noted that the different shapes of the gates 104a and 104b shown in FIG. 14A, FIG. 15A, and FIG. 15B can be applied to all the other embodiments of the cell structures shown herein according to the invention.

The previous embodiments show one conductor plate 132 in the cell structure, however, in accordance with the invention, the cell structure may have multiple conductor plates 132.

FIG. 15C shows a side view of an embodiment of a cell structure having two conductor plates 132a and 132b according to the invention. In other embodiments, the cell structure is configured to have any number of conductor plates.

FIG. 15D shows a cross-section view of the cell structure shown in FIG. 15C taken along line A-A′ shown in FIG. 15C. The multiple conductor plate structure shown in FIG. 15C can be applied to all the other embodiments of the cell structures shown herein according to the invention. It should be noted that the side view shown in FIG. 15C illustrates one half of the cell with the bit line 101 at the right. The top view shown in FIG. 15D illustrates the entire cell with the bit line 101 in the center.

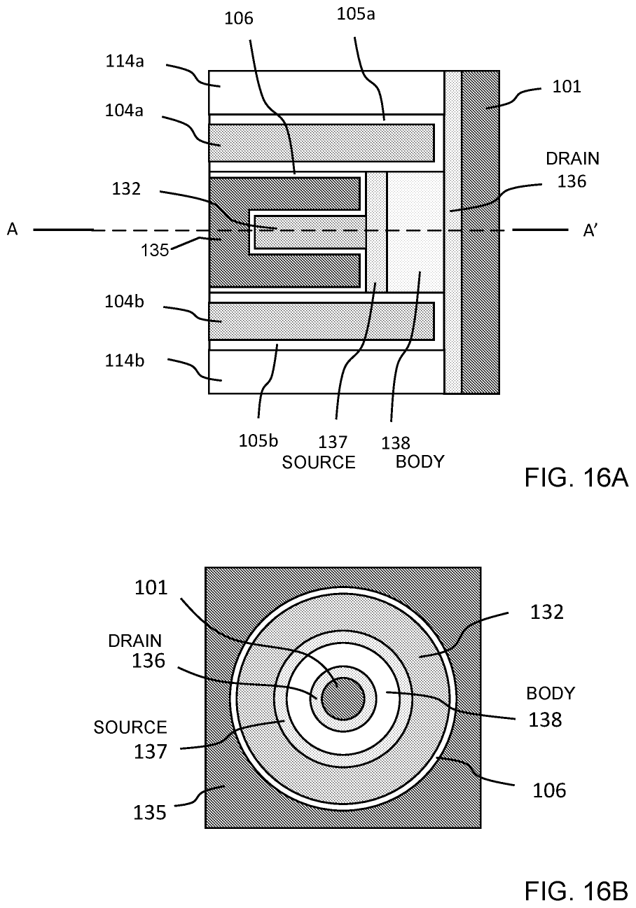

FIGS. 16A-B shows embodiments of a 3D cell structure according to the invention. These embodiments are similar to the embodiments shown in FIGS. 14A-B except select transistors are formed as traditional junction transistors instead of thin-film transistors. As shown in FIG. 16A, drain 136 and source 137 regions are formed of heavily doped semiconductor layers, such as heavily doped silicon layers. A transistor body 138 is formed of lightly doped semiconductor material, such as lightly doped silicon material. In an embodiment, the drain 136 and source 137 regions have the opposite type of doping as the body 137. It should be noted that the side view shown in FIG. 16A illustrates one half of the cell with the bit line 101 at the right. The top view shown in FIG. 16B illustrates the entire cell with the bit line 101 in the center. The junction transistor structure shown in this embodiment can be applied to all the other embodiments of the cell structures shown herein according to the invention.

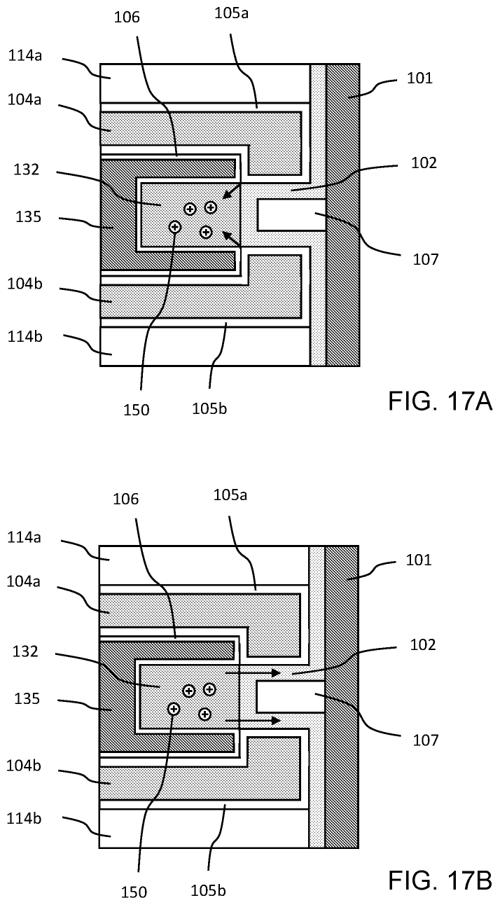

FIGS. 17A-B shows side views of embodiments of a 3D cell structure according to the invention. These embodiments are similar to the embodiment shown in FIG. 15B except that the conductor plate 132 is formed of a P-type semiconductor material, such as silicon or polysilicon material. This allows the semiconductor plate 132 to store electric holes 150 to represent the data. The holes 150 are generated by using any one of many suitable mechanisms. In one embodiment, the holes 150 are generated by using a band-to-band tunneling (BTBT) mechanism. The gates 104a and 104b are supplied with a positive voltage to turn on the channel in the semiconductor layer 102 to pass a suitable positive voltage, such as 2.5V, to the semiconductor plate 132. The semiconductor plate 132 is supplied with a suitable negative voltage, such as −2V. This causes band-to-band-tunneling to occur in the junction between the semiconductor layer 102 and the semiconductor plate 132 to inject holes 150 into the semiconductor plate 132 as shown by the arrows in FIG. 17A. The holes 150 are trapped inside the semiconductor plate 132 when the gates 104a and 104b are supplied with a low voltage, such as 0V, to turn off the channel in the semiconductor layer 102.

FIG. 17B illustrates a read operation. During a read operation, the bit line 101 is pre-charged to a suitable voltage. The gates 104a and 104b are supplied with a positive voltage to turn on the channel in the semiconductor layer 102. The holes 150 stored in the semiconductor plate 132 flow through the channel to the bit line 101, as shown by the arrows in FIG. 17B, and cause charge sharing with the capacitance of the bit line 101. This condition will change the voltage of the bit line 101. If the semiconductor plate 132 stores no hole, the bit line 101 voltage will remain unchanged. A sensing circuit (not shown) is coupled to the bit line 101 to detect the voltage change to determine the data. The cell structure and operations shown in FIGS. 17A-B can be applied to all the other embodiments of the cell structures shown herein according to the invention.

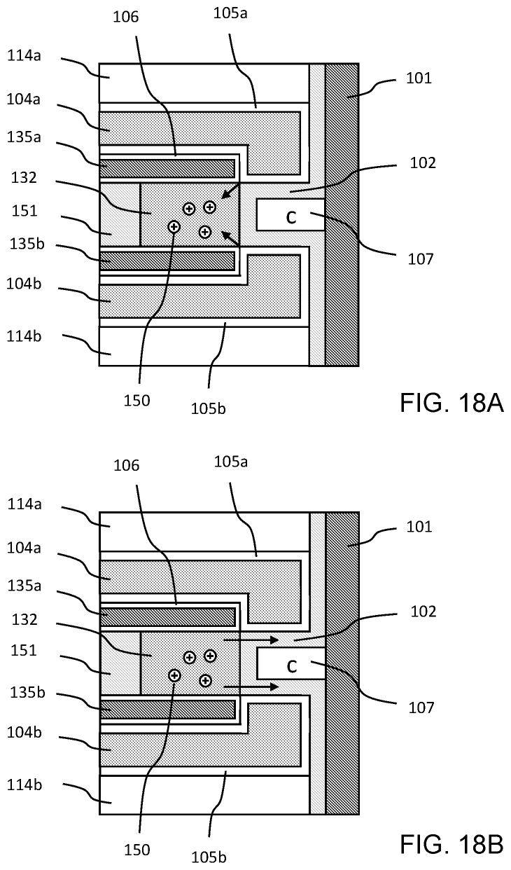

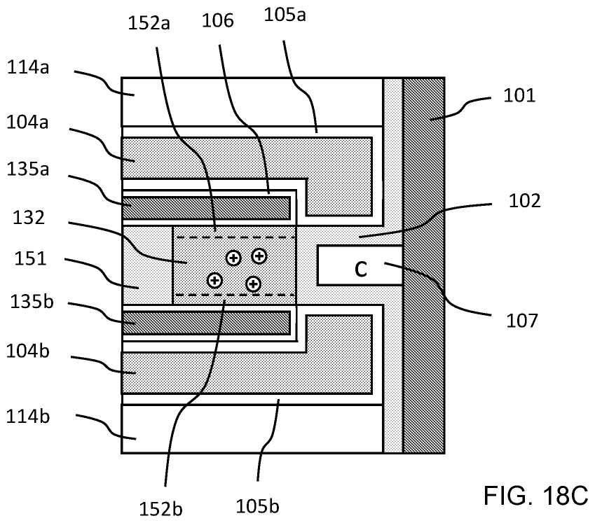

FIGS. 18A-C shows side views of a 3D cell structure according to the invention. This embodiment is similar to the embodiment shown in FIGS. 17A-B except that the semiconductor plate 132 is connected to a source line 151 that is formed of conductor material, such as metal or heavily doped polysilicon material. The semiconductor plate 132 is formed of a P− type semiconductor material, such as silicon or polysilicon material. This allows the semiconductor plate 132 to store electric holes 150 to represent the data. This cell structure is also referred to as a “floating body” cell structure.

The holes 150 are generated using any one of many suitable mechanisms. In one embodiment, the holes 150 are generated by using the band-to-band tunneling (BTBT) mechanism described in FIG. 17A. The reader is referred to the description of FIG. 17A for detailed operations.

In another embodiment, the holes 150 are generated by using an ‘impact ionization’ mechanism. The gates 104a and 104b are supplied with a positive voltage to turn on the channel in the semiconductor layer 102 to pass a suitable positive voltage, such as 2.5V, to the semiconductor plate 132. The conductor layers 135a and 135b are supplied with a low voltage that is higher than the threshold voltage Vt, such as 0.7V to 1V, to weakly turn on the channels in the surface of the semiconductor plate 132 under the conductor layers 135a and 135b. This cause holes 150 to be generated in the junction between the semiconductor layer 102 and the semiconductor plate 132 and the holes 150 are injected into the semiconductor plate 132 as shown by the arrows in FIG. 18A. The holes 150 are trapped inside the semiconductor plate 132 when the gates 104a and 104b are supplied with a low voltage, such as 0V, to turn off the channel in the semiconductor layer 102.

FIG. 18B shows an operation to remove the holes 150 from the semiconductor plate 132. The gates 104a and 104b are supplied with a positive voltage to turn on the channel in the semiconductor layer 102. The bit line 101 is supplied with a negative voltage, such as −1V. This cause P-N forward-bias current to occur from the semiconductor plate 132 through the channel in the semiconductor layer 102 to the bit line 101, as shown by the arrows in FIG. 18B. The current evacuates the holes 150 stored in the semiconductor plate 132.

In another embodiment, the bit line 101 is supplied with 0V. The conductor layers 135a and 135b are supplied with a positive voltage, such as 2V, to cause capacitance-coupling to the semiconductor plate 132. This causes the voltage of the semiconductor plate 132 to be higher than the threshold voltage of the P-N junction and causes P-N forward current to flow from the semiconductor plate 132 to the bit line 101 to evacuate the holes 150.

In another embodiment, a negative voltage, such as −1V or 0V, is supplied to the source line 151 instead of the bit line 101. This causes P-N forward current to occur in the junction between the semiconductor plate 132 and the source line 151 to evacuate the holes to the source line 151.

FIG. 18C illustrates a read operation for the cell. The bit line 101 and the source line 151 are supplied with different voltages, such as 1V and 0V, respectively. The gates 104a and 104b are supplied with a positive voltage to turn on the channel in the semiconductor layer 102. Assuming there are holes 150 stored in the semiconductor plate 132, the holes 150 decrease the threshold voltage of the channels 152a and 152b of the semiconductor layer 132 under the conductor layers 135a and 135b. The conductor layers 135a and 135b are supplied with a read voltage that is higher than the threshold voltage. This turns on the channels 152a and 152b to conduct current from the bit line 101 to the source line 151.

If the semiconductor plate 132 stores no holes, the threshold voltage of the channels 152a and 152b of the semiconductor layer 132 will be higher than the read voltage applied to the conductor layers 135a and 135b. Therefore, the channels 152a and 152b will be turned off and conduct no current. A sensing circuit (not shown) coupled to the bit line 101 detects the current to determine the data. The source line 151 structure and operations shown in FIG. 18A-C can be applied to all the other embodiments of the cell structures shown herein according to the invention.

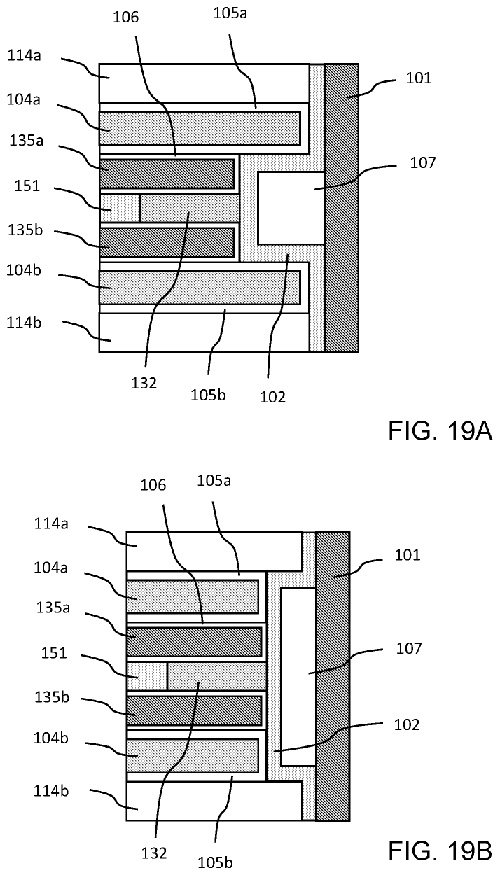

FIGS. 19A-B show embodiments of cell structures having source line configurations similar to the source line 151 in the cell structure embodiments shown in FIG. 14A and FIG. 15A, respectively.

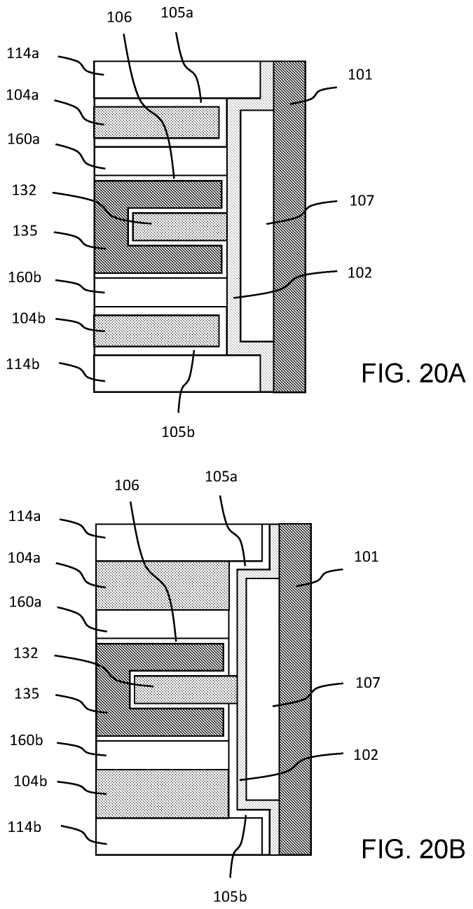

FIG. 20A shows a side view of another embodiment of a 3D cell structure according to the invention. This embodiment is similar to the embodiment shown in FIG. 15A except that additional insulating layers 160a and 160b comprising material such as oxide or nitride are formed between the conductor layer 135 and the gates 104a and 104b. This configuration reduces the parasitic capacitance of the gates 104a and 104b to reduce the RC delay of the gates. This configuration also reduces the capacitance coupling of the gates 104a and 104b to the conductor layer 135. This feature can be applied to all the other embodiments of the cell structures shown herein according to the invention.

FIG. 20B shows a side view of another embodiment of a 3D cell structure according to the invention. This embodiment is similar to the embodiment shown in FIG. 20A except that the gate dielectric layers 105a and 105b are formed in different shapes. In FIG. 20A, the gate dielectric layers 104a and 104b are formed to surround the gates 104a and 104b. In FIG. 20B, the gate dielectric layers 104a and 104b are formed on the sidewall of the semiconductor layer 102. This configuration of the gate dielectric layers can be applied to all the other embodiments of the cell structures shown herein according to the invention.

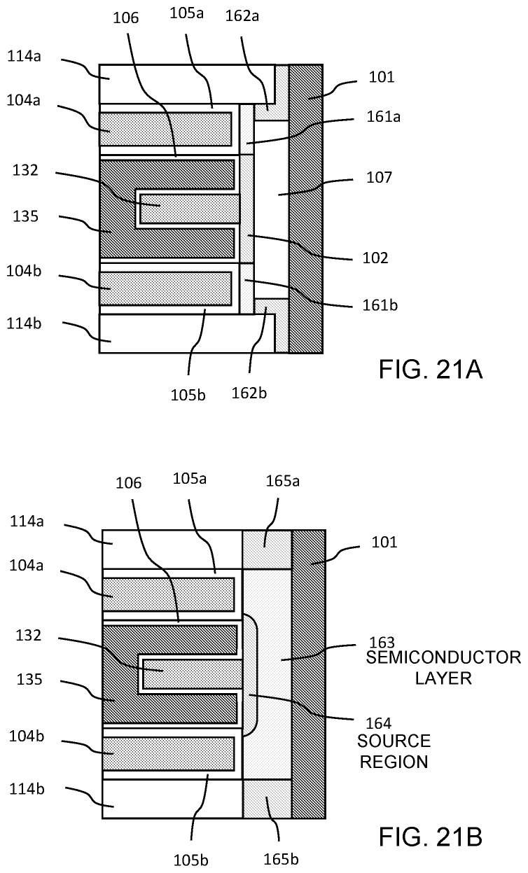

FIG. 21A shows a side view of another embodiment of a 3D cell structure according to the invention. This embodiment is similar to the embodiment shown in FIG. 15A except that additional channel regions 161a and 161b are formed in the semiconductor layer 102. In one embodiment, the channel regions 161a and 161b are formed by using an isotropic doping process, such as plasma doping or gas-phase doping, to dope the semiconductor layer 102 with the opposite type of dopants to reverse the doping type of the channel regions 161a and 161b. For example, if the semiconductor layer 102 has N+ doping, the channel regions 161a and 161b are doped with P− type of dopants, such as boron, to form P− channel regions. If the semiconductor layer 102 has P+ doping, the channel regions 161a and 161b are doped with N-type of dopants, such as phosphorus, to form N− channel regions.

In one embodiment, the doping process is performed through the spaces occupied by the gates 104a and 104b before the gates 104a and 104b and the gate dielectric layers 105a and 105b are formed. The features shown in FIG. 21A can be applied to all the other embodiments of the cell structures shown herein according to the invention.

FIG. 21B shows a side view of another embodiment of a 3D cell structure according to the invention. This embodiment is similar to the embodiment shown in FIG. 15A except that the transistor of the cell is formed as a junction transistor. The cell structure includes a semiconductor layer 163 comprising material such as silicon or polysilicon that forms the body of the transistor. The semiconductor layer 163 may have P type or N type of doping. A source region 164 is formed by using an isotropic doping process, such as plasma doping or gas-phase doping, to dope the semiconductor layer 163 with the opposite type of dopants such as N type or P type of dopants. In one embodiment, the doping process is applied through the space occupied by the conductor plate 132 and the conductor layer 135 before the conductor plate 132 and the conductor layer 135 and the dielectric layer 106 are formed.

In one embodiment, drain regions 165a and 165b are formed of semiconductor material having the opposite type of doping as the semiconductor layer 163. For example, in one embodiment, the semiconductor layer 163 has P− doping and the source region 164 and drain regions 165a and 165b have N+ doping. In another embodiment, the semiconductor layer 163 has N− doping and source region 164 and drain regions 165a and 165b have P+ doping.

In this embodiment, the bit line 101 is formed of heavily doped semiconductor material, such as heavily doped silicon or polysilicon material, having the opposite type of doping as the semiconductor layer 163. In another embodiment, if the bit line 101 is formed of metal, an insulating layer (not shown) comprising oxide or nitride is formed between the semiconductor layer 163 and the bit line 101 to prevent them from shorting. The features shown in FIG. 21B can be applied to all the other embodiments of the cell structures shown herein according to the invention.

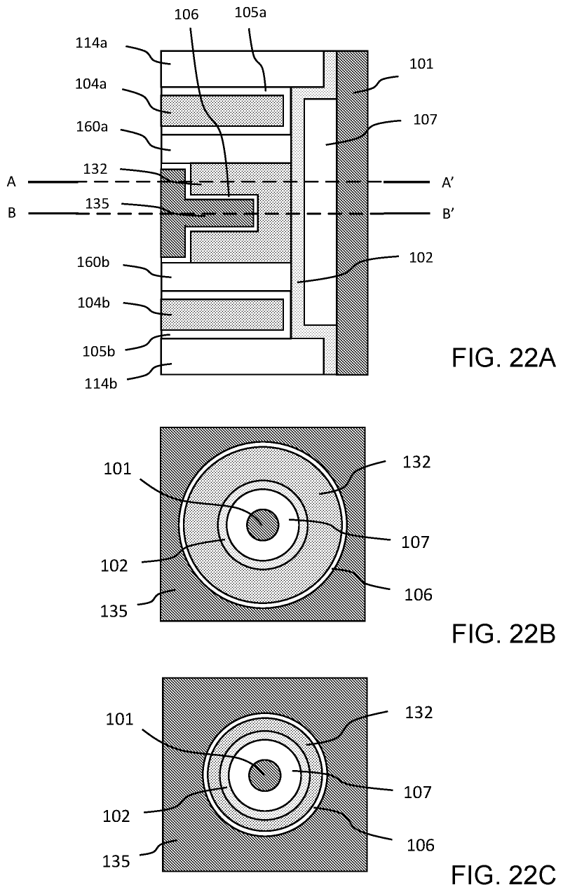

FIGS. 22A-C shows another embodiment of a 3D cell structure according to the invention. This embodiment is similar to the embodiment shown in FIG. 20A except that the capacitor formed by the conductor plate 132 and the conductor layer 135 are formed in different shapes. For example, in FIG. 20A, the conductor layer 135 encloses the conductor plate 132 and in FIG. 22A, the conductor plate 132 encloses the conductor layer 135.

In this embodiment, the insulating layers 160a and 160b comprise material, such as oxide or nitride material, and are formed between the conductor plate 132 and the gates 104a and 104b. This configuration reduces the capacitance coupling from the gates 104a and 104b to the conductor plate 132. In another embodiment, the insulating layers 160a and 160b are eliminated to form a cell structure similar to the embodiment shown in FIG. 15A. The shape of the capacitor shown in this embodiment can be applied to all the other embodiments of the cell structures shown herein according to the invention.

FIG. 22B-C show top cross-section views of the cell structure shown in FIG. 22A taken along lines A-A′ and B-B′, respectively.

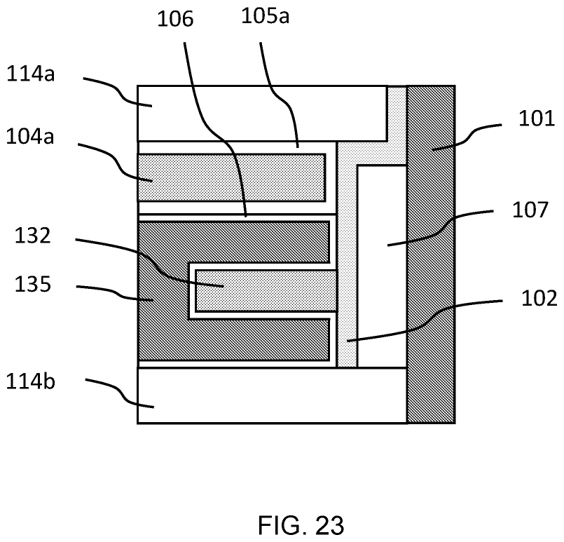

FIG. 23 shows another embodiment of a 3D cell structure according to the invention. This embodiment is similar to the embodiment shown in FIG. 15A except that the gate 104b and the gate dielectric layer 105b are eliminated. The cell has only one gate 104a and an insulating layer 114b comprising material such as oxide or nitride material. This embodiment reduces the height of the cell. The reduced cell height allows more cells to be stacked in the 3D array. This feature can be applied to all the other embodiments of the cell structures shown herein according to the invention.

Although the embodiments shown in FIGS. 20A-23 use the cell structure shown in FIG. 15A for illustration purposes, it is obvious that the features of the embodiments shown in FIG. 20A-23 can be also applied to all the other embodiments of the cell structures shown herein according to the invention.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A memory cell structure, comprising:
a vertical bit line;
an insulator surrounding a first portion of vertical bit line;
a continuous semiconductor layer surrounding the insulator and a second portion of the vertical bit line;
an extended portion of conductor material surrounding the continuous semiconductor layer;
a first dielectric layer surrounding extended portion of conductor material;
a first conductor layer surrounding the first dielectric layer;
a second conductor layer surrounding the first conductor layer;
a second dielectric layer on a top surface of the first and second conductor layers;
a third dielectric layer on a bottom surface of the first and second conductor layers;
a first gate on a top surface of the second dielectric layer; and
a second gate on a bottom surface of the third dielectric layer.

2. A memory cell structure, comprising:
a vertical bit line;
an insulator surrounding a first portion of vertical bit line;
a continuous semiconductor layer surrounding the insulator and a second portion of the vertical bit line;
an extended portion of conductor material surrounding a first portion of a side surface of the continuous semiconductor layer;
a first dielectric layer surrounding the extended portion of conductor material and a second portion of the side surface of the continuous semiconductor layer;
a first conductor layer surrounding the first dielectric layer;
a second dielectric layer above a top surface of the first conductor layer;
a third dielectric layer below a bottom surface of the first conductor layer;
a second conductor layer on a top surface of the first dielectric layer; and
a third conductor layer on a bottom surface of the third dielectric layer.
